(19) United States
(12) Patent Application Publication
(10) Pub. No.: US 2007/0218190 A1
(43) Pub. Date: Sep. 20, 2007

(54) METHOD FOR MANUFACTURING LIGHT-EMITTING ELEMENT, LIGHT-EMITTING DEVICE, AND ELECTRONIC APPARATUS

(75) Inventors: Takeshi TAKASHIMA, Kawasaki-shi (JP); Koichi TERAO, Suwa-shi (JP); Takashi SHINOHARA, Suwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/688,126

(22) Filed: Mar. 19, 2007

(30) Foreign Application Priority Data
Mar. 20, 2006 (JP) 2006-077831

(51) Int. Cl. B05D 5/06; B05D 5/12

(52) U.S. Cl. 427/66; 427/64

(57) ABSTRACT

A method for manufacturing a light-emitting element, including: forming a film on one side of a first electrode; obtaining a light-emitting layer in the film by polymerizing a first compound as well as at least one of a second compound and a third compound; and installing a second electrode on a side opposite from the first electrode in the light-emitting layer; wherein: the first compound is provided with an emissive light-emitting moiety and a first polymerizable group; the second compound is provided with a hole-transporting hole transport moiety and a second polymerizable group; and the third compound is provided with an electron-transporting electron transport moiety and a third polymerizable group.

### BACKGROUND

1. Technical Field

Several aspects of the present inventions relates to a method for manufacturing a light-emitting element, a light-emitting device, and an electronic apparatus.

2. Related Art

There are electroluminescence (EL) elements that have light-emissive organic layers (organic EL layers) provided between cathodes and anodes. Those organic EL elements significantly reduces the required level of voltages applied thereto, when compared with inorganic EL elements, allowing to manufacture elements with great diversity of colors emitted therefrom.

As described, each of these organic EL elements has a cathode and an anode, and an organic EL layer is provided therebetween.

This organic EL layer is typically provided with three layers; a hole transport layer, a light-emitting layer, and an electron transport layer. In some cases, additional layer may also be added. JP-A-2005-302667 is an example of related art.

If the constituent materials dissolving into a solvent have similar solubility in adjacent organic EL layers, then the constituent materials blend-in to each other at the vicinity of surfaces between the top and the bottom layers. This is caused by the elution of the constituent materials of the bottom layer, eluted by the solvent used for deposition of the top layer. As a result, the performance of these layers is impaired, decreasing luminous efficiency.

Therefore, when forming the organic EL layers, it is common to select different materials for the top and bottom layers, having different solubility in a solvent. This disadvantageously limits the selection of materials with suitable device characteristics.

In order to overcome such disadvantages, providing an organic EL layer as a single layer has been considered. In recent years, suggestions have been made to form an organic EL layer (single layer) with a block copolymer in order to make the layer light emissive. The block copolymer has units by functions each provided in a single molecule, and such units may include a hole transportable unit, an electron transportable unit, and a luminescent unit (refer to PCT/GB2001/001037 is an example of related art).

Unfortunately, synthesizing such block copolymers requires numerous processes with a low yield.

### SUMMARY

An advantage of the present invention is to provide methods for manufacturing a light-emitting element, a light-emitting device, and an electronic apparatus, each of which provides advantages as follows. A method for manufacturing a light-emitting element allows producing an element with excellent light-emitting characteristics such as luminous efficiency in a relatively simple process. A method for manufacturing a light-emitting device includes the method for manufacturing a light-emitting element, and provides a highly reliable light-emitting device. A method for manufacturing an electronic apparatus includes the method for manufacturing a light-emitting device, and provides highly reliable electronic apparatus.

The advantage of the invention is achieved by the following aspects of the invention.

According to a first aspect of the invention, a method for manufacturing a light-emitting element includes: forming a film on one side of a first electrode; obtaining a light-emitting layer in the film by polymerizing a first compound as well as at least one of a second compound and a third compound; and installing a second electrode on a side opposite from the first electrode in the light-emitting layer.

The first compound is provided with an emissive light-emitting moiety and a first polymerizable group. The second compound is provided with a hole-transporting hole transport moiety and a second polymerizable group. The third compound is provided with an electron-transporting electron transport moiety and a third polymerizable group.

This allows, in a relatively simple process, a manufacturing of a light-emitting device having excellent light-emitting characteristics such as luminous efficiency.

In this case, it is desirable in forming a film that the film be formed with a liquid phase process.

This is because the liquid phase process allows a film to be formed in a relatively simple process without using large-scale devices. This simple process supplies, to one side of the electrode, liquid material containing the first compound as well as at least one of the second compound and the third compound.

In this case, it is desirable, in obtaining a light-emitting layer, that the first compound, as well as at least one of the second compound and the third compound be polymerized by light irradiation.

This is because the light irradiation that directs a light beam to the film allows relatively an easy control over the reaction speed of polymerization, and, at the same time, provides a high degree of selectivity in polymerization region.

In this case, in obtaining a light-emitting layer, the first compound, as well as at least one of the second compound and the third compound may be polymerized by heating.

This is desirable since the heating treatment that heats the film allows relatively an easy control over the reaction speed of polymerization.

It is desirable, in the method for manufacturing a light-emitting element, that a plurality of polymerizable groups be included in at least one of the first compound, the second compound, and the third compound.

Consequently, random copolymers contained in the light-emitting layer obtain a three-dimensional network structure in which the random copolymers are linked so as to form a network, and not a linear straight chain structure. This allows an improvement in the heat resistance of the light-emitting layer, as well as in the efficiency of the carrier implantation to the light-emitting moiety.

In this case, all the polymerizable groups may be cation polymerizable among the first polymerizable group, the second polymerizable group, and the third polymerizable group.

This provides a uniform reactivity of the first, the second, and the third polymerizable groups, thereby reliably randomizing the first and the second compounds.

In this case, all the polymerizable groups may be radical polymerizable among the first polymerizable group, the second polymerizable group, and the third polymerizable group.

This provides a uniform reactivity of the first, the second, and the third polymerizable groups, thereby reliably randomizing the first and the second compounds.

It is desirable, in the method for manufacturing a light-emitting element, that the hole transport moiety includes an arylamin skeleton.

Such hole transport moiety provides an excellent hole transportability. It also allows a relatively easy introduction (linking) of the second polymerizable group.

It is desirable, in the method for manufacturing a light-emitting element, that the electron transport moiety includes at least one of an oxadiazole skeleton and a triazole skeleton.

Such electron transport moiety provides an excellent hole transportability. It also allows a relatively easy introduction (linking) of the second polymerizable group.

It is desirable, in the method for manufacturing a light-emitting element, that the light-emitting moiety includes at least one of a fluorenone skeleton and a carbazol skeleton.

Such light-emitting moiety is highly luminescent. It also allows a relatively easy introduction (linking) of the first polymerizable group.

In this case, the light-emitting moiety may include at least one of an iridium complex and an aluminum complex.

Such light-emitting moiety is highly luminescent. It also allows a relatively easy introduction (linking) of the first polymerizable group.

It is desirable, in the method for manufacturing a light-emitting element, that the film includes a fourth compound provided with a host moiety supplying an excitation energy to the light-emitting moiety.

The re-bonding of the hole and the electron may cause the energy loss in the host moiety. However, the above method reliably reduces this energy loss, thereby improving the luminous efficiency in the light-emitting moiety in the formed light-emitting layer.

In this case, the fourth compound may include a fourth polymerizable group.

Consequently, the random copolymer is produced in the light-emitting layer being formed, as a result of polymerizing the first compound, the fourth compound, and at least one of the second and the third compounds.

In this case, the host moiety may include at least one of an arylamin skeleton, a carbazol skeleton, and a fluorenone skeleton.

Such host moiety is desirable since those skeletons have particularly large band gaps.

According to a second aspect of the invention, a method for manufacturing a light-emitting device includes the method for manufacturing a light-emitting element according to the first aspect of the invention.

This allows a manufacturing of a highly reliable light-emitting device.

According to a third aspect of the invention, a method for manufacturing an electronic apparatus includes the method for manufacturing a light-emitting device according to the second aspect of the invention.

The highly reliable electronic apparatus can be manufactured using the above method.

### BRIEF DESCRIPTION OF THE DRAWINGS

The invention will be described with reference to the accompanying drawings, wherein like numbers reference like elements.

FIG. 1 is a schematic cross-sectional view of the light-emitting element according to one embodiment of the invention, manufactured with a method for manufacturing the light-emitting device.

FIGS. 2A through 2G are schematic illustrations showing various structures of an organic EL layer included in the light-emitting element.

FIG. 3 is a cross-sectional view of a display device provided with the light-emitting element according to one embodiment of the invention.

FIG. 4 is a perspective view of a mobile (or notebook) personal computer provided with a light-emitting device.

FIG. 5 is a perspective view of a mobile phone (including a personal handy-phone system), provided with the light-emitting device.

FIG. 6 is a perspective view of a digital still camera provided with the light-emitting device.

### DESCRIPTION OF EXEMPLARY EMBODIMENTS

Suitable embodiments of the method for manufacturing a light-emitting element, a light-emitting device, and an electronic apparatus will now be described with reference to the attached drawings.

Light-Emitting Element

The light-emitting element (organic EL element) manufactured with the method for manufacturing the light-emitting element according to the embodiments of the invention will now be described.

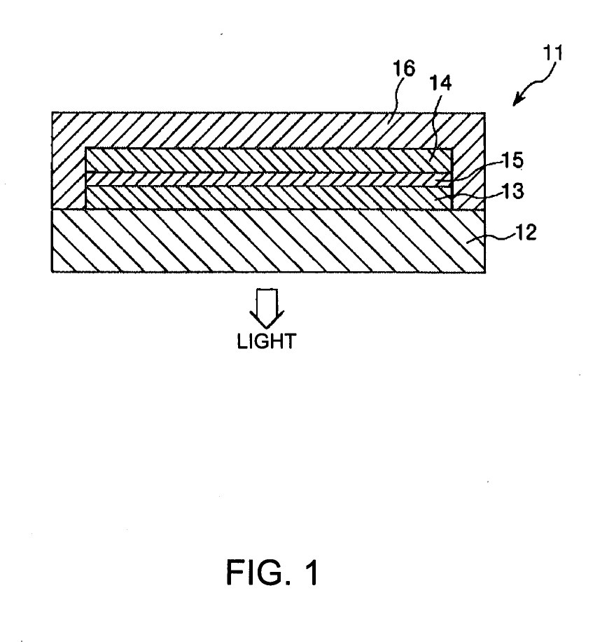

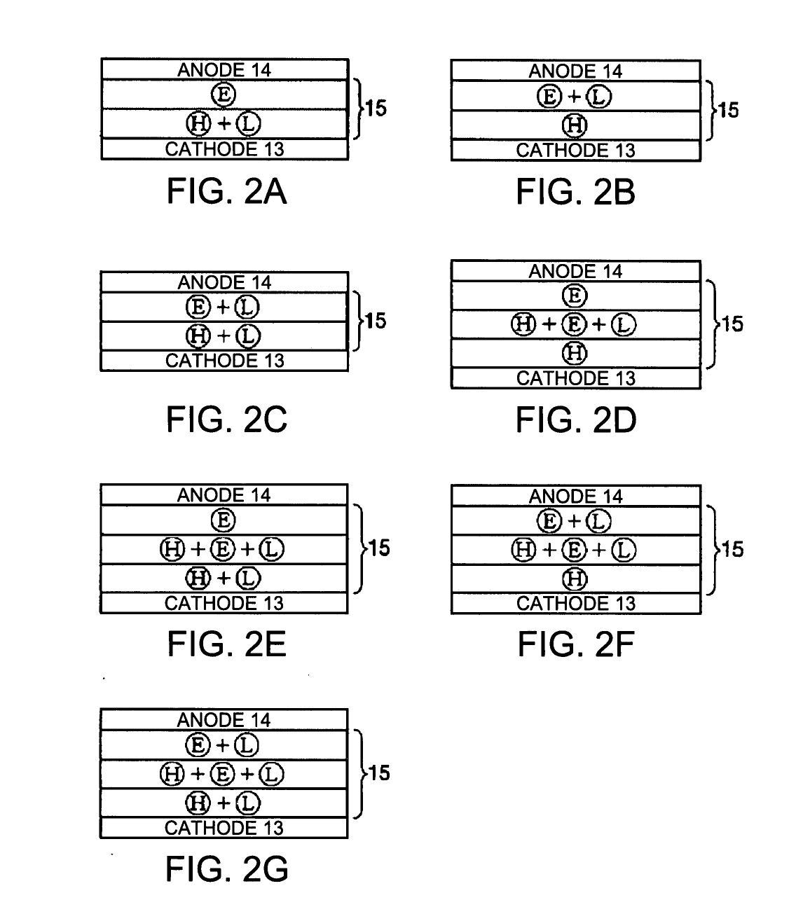

FIG. 1 is the schematic cross-sectional view of the light-emitting element according to one embodiment of the invention, manufactured with a method for manufacturing the light-emitting device. FIGS. 2A through 2G are schematic illustrations showing various structures of an organic EL layer included in the light-emitting element. Hereafter, the upper side of FIGS. 1 and 2 is defined as “top”, and the lower side thereof is defined as “bottom”, for the convenience of explanation.

A light-emitting device (organic EL element) 11 referred to in FIG. 1 includes an anode 13 provided on a substrate 12, a cathode 14, and an organic EL layer 15 provided between the anode 13 and the cathode 14. A sealer 16 seals up the anode 13, the cathode 14, and the organic EL layer 15.

The substrate 12 supports the light-emitting element 11. The substrate 12 and the anode 13 are substantively transparent. In other words, they may either be clear and colorless, clear with coloring, or translucent, since the light-emitting element 11 according to this embodiment has a bottom emission structure, extracting the light beam from the direction of the substrate 12.

For instance, examples of constituent materials of the substrate 12 include: resins such as polyethylene terephthalate, poly(ethylene naphthalate), polypropylene, cycloolefin polymer, polyamide, polyethersulfone, polymethyl methacrylate, polyarylate; and glass materials such as quartz glass and soda glass. These materials may be used alone or in combination of two or more.

The preferable range for the average thickness of such substrate 12 includes, but is not limited to, approximately 0.1 mm to 30 mm. Particularly, a range approximately from 0.1 mm to 10 mm is preferable.

Both transparent and opaque substrates may be used for the substrate 12, if the light-emitting element 11 is used for a top-emission system, in which the light is extracted from the opposite side of the substrate 12.

Examples of opaque substrates include: substrates composed with ceramics such as alumina, substrates where an oxide film (insulation film) is deposited on the surface of metal substrates such as stainless steal, and substrates composed with resins.

The anode 13 is an electrode that implants holes to the organic EL layer 15. Materials with superior conductivity having a high work function are preferable for the materials for the anode 13.

Examples of constituent materials of the anode 13 include: oxides such as indium tin oxide (ITO), indium zinc oxide (IZO), In₃O₃, SnO₂, Sb-doped SnO₂, Al-doped ZnO; and Au, Pt, Ag, Cu and alloys containing them. These materials may be used alone or in combination of two or more.

The preferable range for the average thickness of such anode 13 includes, but is not limited to, approximately 10 to 200 nm. Particularly, a range approximately from 50 to 150 nm is preferable.

The cathode 14 is an electrode that implants electrons to the organic EL layer 15. Materials having a low work function are preferable for the materials for the anode 14.

Examples of constituent materials of the cathode 14 include: Li, Mg, Ca, Sr, La, Ce, Er, Eu, Sc, Y, Yb, Ag, Cu, Al, Cs, Rb, Cr, Oy, Nd and alloys containing them. These materials may be used alone or in combination of two or more (for instance, multilayer structure having a plurality of layers).

In the case of using alloys as materials for constituting the cathode 14, alloys containing stable metallic element such as Ag, Al, Cu, specifically, alloys such as MgAg, AlLi, CuLi. This improves the carrier implantation efficiency and stability of the cathode 14.

The preferable range for the average thickness of such cathode 14 includes, but is not limited to, approximately 100 to 10000 nm. Particularly, a range approximately from 200 to 500 nm is preferable.

The light-emitting element 11 according to this embodiment employs a bottom-emission model, and thus does not require the cathode 14 to have optical transparency.

The organic EL layer (light-emitting layer) 15 is provided between the anode 13 and the cathode 14, the layer contacting both of the electrodes.

When applying a current (impressing a voltage) between the anode 13 and the cathode 14, holes and electrons are implanted to the organic EL layer 15 from the anode 13 and the cathode 14 respectively. Re-bonding of holes and electrons causes the organic EL layer 15 to emit light.

There is an advantage in using a process for forming this organic EL layer 15 in accordance with a method for manufacturing a light-emitting element according to one embodiment of the invention. The organic EL layer 15, formed with the method for manufacturing the light-emitting element according to one embodiment of the invention described later, will now be described.

The organic EL layer 15 is composed with random copolymers obtained by polymerizing the first compounds with at least one of the second and the third compounds. The first compound includes the luminescent light-emitting moiety and the first polymerizable group. The second compound includes the hole-transporting hole transport moiety and the second polymerizable group. The third compound includes the electron-transporting electron transport moiety and the third polymerizable group. The polymerization is carried out with the first and at least one of a second and a third polymerizable groups of those compounds.

In other words, the organic EL layer 15 includes polymers in which the light-emitting moiety and at least one of the hole transport moiety and the electron transport moiety are linked in optional sequence, having therebetween a link structure formed by polymerizing the first polymerizable group and at least one of the second and the third polymerizable groups.

The first, the second, and the third compounds will now be described in this order.

The first compound includes the luminescent light-emitting moiety and the first polymerizable group liked to this light-emitting moiety.

The light-emitting moiety is provided with a functions to emit fluorescence or phosphorescent light generated by the rebonding of the holes and electrons that are implanted into the organic EL layer 15.

The hole and the electron implanted into the organic EL layer 15 are supplied to the light-emitting moiety and are rebonded. As a result, excitons (exciters) are generated by energies released upon rebonding, and energies (fluorescence or phosphorescent light) are released (emitted) at the light-emitting moiety, when these excitons return to the ground state.

Examples of materials constituting the light-emitting moiety include: polymers having at least one of the skeletons of carbazole, of fluorenone, and of paraphenylene vinylene; pigments such as perylene, rubrene, quinacridone, coumarin, nile red; and metallic complexes of metals such as aluminum, iridium, beryllium, and zinc. In particular, the examples of materials the light-emitting moiety may preferably be composed of, include: polymers having a carbazole skeleton, or a fluorenone skeleton; and complexes such as aluminum complex and iridium complex. The light-emitting moiety composed of the materials described above is particularly highly luminescent, allowing a relatively easy introduction (linking) of the first polymerizable group.

Examples of compounds of the light-emitting moiety containing the above are represented by formulae 1-1 to 1-6.

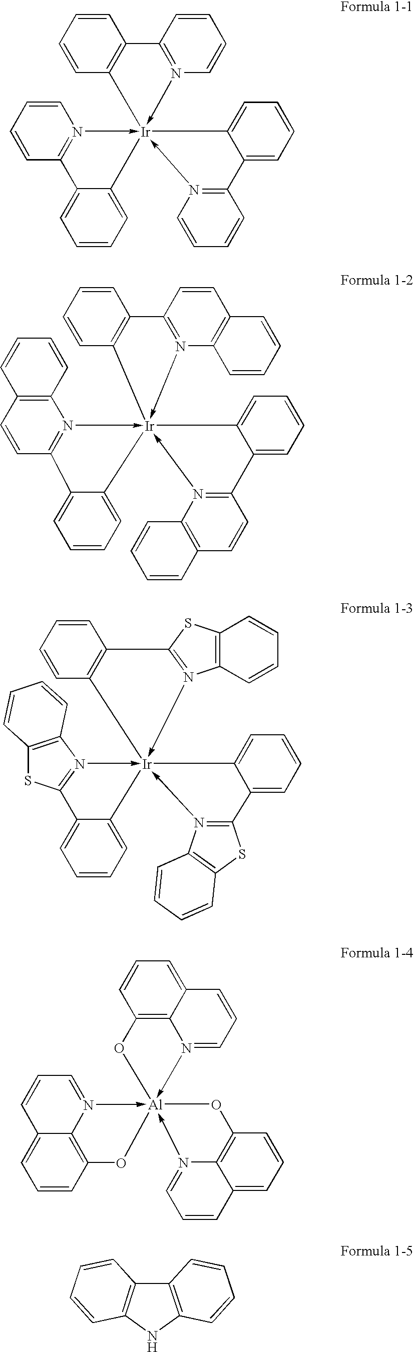

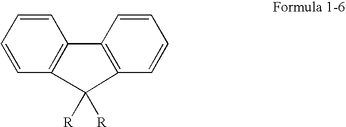

A first R and a second R independently represents hydrogen atom or alkyl.

These light-emitting moieties may have a single or a plurality of substituents introduced thereto, so as to adjust the properties such as: a solubility of the first compound to a solvent, and a color the light-emitting moieties emit. Examples of such substituents include, but are not limited to, halogen atoms such as fluorine atom, and linear C6-C12 alkyl.

When exitons return to the ground state, these light-emitting moieties represented by formulae 1-1 to 1-3 emit phosphorescent light, and the ones represented by formulae 1-4 to 1-6 emit fluorescence light.

The first polymerizable group is polymerized with the adjacent first, second, and third polymerizable groups respectively contained by the first, the second and the third compounds. The first polymerizable group thereby links the first compound to: another first compound (light-emitting moiety); the second compound (hole transport moiety); and the third compound (electron transport moiety).

There is no specific limitation to the composition of the first polymerizable group, as long as polymerization is carried out by the predetermined treatments such as light irradiation or heating, in accordance with the later-described method for manufacturing a light-emitting element. Examples of such polymerizable group include substituents terminated with: cyclic ethers such as epoxy and oxetane; alkenyls such as (meth)acryloyl, vinyl ether, vinylbenzyl ether, vinyl, and allyl. The variation of this first polymerizable group is optionally selected, in accordance with the type of polymerization initiator described later, or the predetermined treatments described above.

Among the first polymerizable group, substituents terminated with the cyclic ether groups are radical polymerizable. Substituents terminated with alkenyl groups are cation polymerizable.

At least one, but preferably more than one first polymerizable groups need to be introduced to the first compound. It is desirable that the plurality of first polymerizable groups is linked to the light-emitting moiety. Consequently, the number of compounds linked to the first compound increases. The compounds linking to the first compound (light-emitting moiety) are the first compound (light-emitting moiety) and at least one of the second compound (hole transport moiety) and the third compound (electron transport moiety). At the same time, distances between the light-emitting moieties as well as between the light-emitting moiety and the carrier transport moiety are retained (defined) to a predetermined value. Thus, the efficiency of carrier implantation implanted to the host moieties increases. Further, the random copolymers, being linked so as to form a network, obtain a three-dimensional network structure, and not a linear straight chain structure. This allows improvement in the heat resistance of the light-emitting layer, as well as in the efficiency of the carrier implantation implanted to the light-emitting moieties.

If the first compound contains a plurality of the first polymerizable groups, the groups may either be of the same kind (or identical) or of a different kind. However, groups of the same kind, identical ones in particular, are preferable. This provides a uniform reactivity among the first polymerizable groups, thereby reliably randomizing the linking of the first compound to another first compound, as well as to at least one of the second and the third compounds.

The organic EL layer 15 (random copolymer) may contain identical first compounds provided with the light-emitting moieties, but may also have variations in the composition of the light-emitting moiety. This enables the color emitted by the organic EL layer 15 to be adjusted to a desirable one.

The organic EL layer 15 may further include luminescent compounds that does not link with the random copolymer. There is no specific limitation to the composition of the luminescent compound. Examples of compounds listed for light-emitting moiety, in other words, compounds having compositions in which the first polymerizable groups are excluded from the first compounds are suitably used.

The second and the third compounds include the carrier-transporting carrier transport moieties, as well as the second and the third polymerizable groups respectively linked to the carrier transport moieties.

The carrier transport moieties include the hole transport moiety that transports holes implanted from the anode 13 to the light-emitting moiety, and the electron transport moiety that transports electrons implanted from the cathode 14.

In other words, the second compound is a compound provided with the hole-transporting hole transport moiety, and the third compound is a compound provided with the electron-transporting electron transport moiety. The organic EL layer 15 may preferably include both the second and the third compounds. This improves the implantation efficiency of both the holes and the electrons implanted to the light-emitting moiety, allowing the light-emitting moiety to emit light more reliably.

Examples of the hole transport moiety include compounds containing skeletons such as: arylamin, dioxy thiophene, carbazol, phthalocyanine, and porphyrin. Particularly, the compounds including arylamin skeleton is preferable. The hole transport moieties containing the above skeletons in particular provide excellent hole transportability. These skeletons also allow a relatively easy introduction (linking) of the second polymerizable groups (described later) to the hole transport moieties. Thus such hole transport moieties are preferable.

Examples of compounds of the hole transport moiety containing the arylamin skeleton include compounds represented by formulae 2-1 to 2-6.

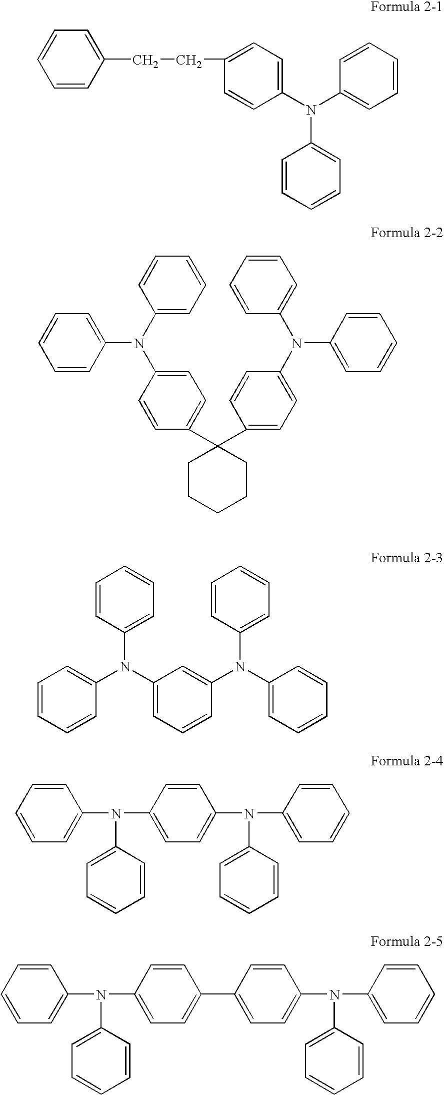

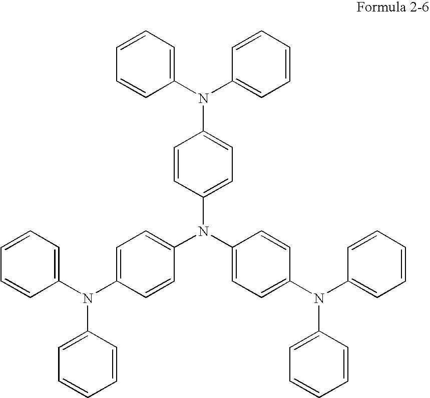

These hole transport moieties may have one or more substituents introduced thereto, so as to adjust properties such as the solubility of the second compound to a solvent, and the hole transportability of the second compound. Examples of such substituents include, but are not limited to, halogen atoms such as fluorine atom, and linear C6-C12 alkyl.

Examples of the electron transport moiety include compounds containing skeletons of azoles such as oxadiazole, thiadiazole, triazole, as well as skeletons such as triazine and pyridine. Particularly, compound including oxadiazole or triazole skeleton is preferable. Such electron transport moieties containing the above skeletons provide an excellent electron transportability in particular. These skeletons also allow a relatively easy introduction (linking) of the third polymerizable groups (described later) to the electron transport moieties. Thus such electron transport moieties are preferable.

Examples of the electron transport moiety containing the oxadiazole skeleton include compounds represented by formulae 3-1 to 3-4.

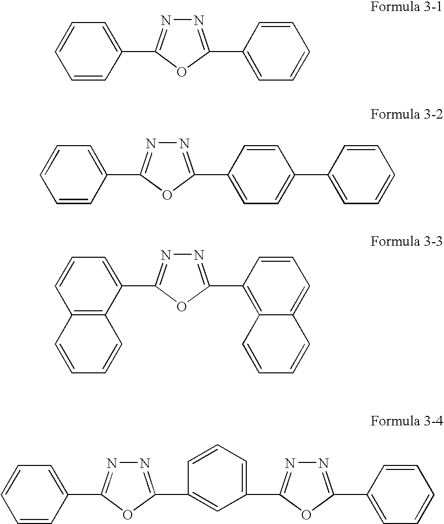

Examples of the electron transport moiety containing the triazole skeleton include compounds represented by formulae 4-1 and 4-2.

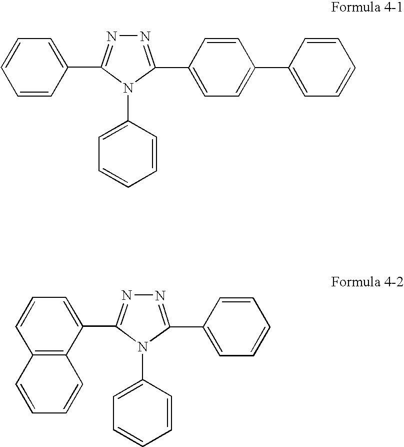

These electron transport moieties may have one or more substituents introduced thereto, so as to adjust properties such as the solubility of the third compound to a solvent, and the electron transportability of the third compound. Examples of such substituents include, but are not limited to, halogen atoms such as fluorine atom, and linear C6-C12 alkyl.

The second polymerizable group is polymerized with the adjacent first, second, and third polymerizable groups respectively contained by the first, the second and the third compounds, linking the second compound to: another second compound (hole transport moiety); the first compound (light-emitting moiety); and the third compound (electron transport moiety).

The third polymerizable group is polymerized with the adjacent first, second, and third polymerizable groups respectively contained by the first, the second and the third moieties, linking the third compound to: another third compound (electron transport moiety); the first compound (light-emitting moiety); and the second compound (hole transport moiety).

The same substituent as that of the first polymerizable group may be used for the second and the third polymerizable group.

The number of the second and the third polymerizable groups that need to be introduced to the second and the third compounds is at least one, but preferably, more than one. It is desirable that one or more second and third polymerizable groups are linked to the carrier transport moiety. Consequently, the second and the third compounds (carrier transport moiety) have more of the first compound (light-emitting moiety) as well as the second and the third compounds. At the same time, distances between the carrier transport moieties as well as between the light-emitting moiety and the carrier transport moiety are retained (defined) to a predetermined value. Thus, the efficiency of carrier implantation from the carrier moieties to the light-emitting moieties increases. Further, the random copolymers, linked so as to form a network, obtain the structure (shape) of a three-dimensional network, and not a linear structure. This allows improvement in the heat resistance of the light-emitting layer, as well as in the efficiency of the carrier implantation from the carrier moieties to the light-emitting moieties.

If the second and the third compounds contain a plurality of the second and the third polymerizable groups, these groups may either be of the same kind (identical) or of a different kind. However, groups of the same kind, identical ones in particular, are preferable. This provides a uniform reactivity of the second and the third polymerizable groups, thereby reliably randomizing the linking of the first compound to the second and the third compounds.

The first, the second, and the third polymerizable groups may either be of the same kind (identical) or of a different kind. However, groups of the same kind, identical ones in particular, are preferable. This provides a uniform reactivity of the first, the second, and the third polymerizable groups, thereby reliably randomizing the first, the second, and the third compounds.

The organic EL layer 15 (random copolymer) may contain identical second compounds, but may have variations in the composition of the hole transport moiety. Similarly, the organic EL layer 15 (random copolymer) may contain identical third compounds, but may have variations in the composition of the electron transport moiety.

The organic EL layer 15 may further include, in addition to the first, the second, and the third compound described above, the fourth compound provided with the host moiety that supplies the excitation energy to the light-emitting moiety.

Since such fourth compound is included in the organic EL layer 15, at least part of the holes and electrons are implanted into the host moiety, without being implanted (supplied) to the light-emitting moiety. The excitation energy is then moved from the host moiety onto the light-emitting moiety (guest).

The hole implanted from the anode 13 and the electron implanted from the cathode 14 are supplied to the host moiety, and they are re-bonded at this host moiety. Excitons (exciters) are generated by an energy released upon the rebonding. The excitation energy is released when these excitons return to the ground state, and is moved onto the light-emitting (guest) moiety. The excitons generated by this excitation energy emit fluorescence or phosphorescent light when returning to the ground state. The luminous efficiency of the light-emitting moiety is improved, since the above composite reliably reduces the energy loss occurring upon hole-electron re-bonding in the host moiety.

While various compounds may be used for the host moiety, the ones preferably used have 3 eV or more of a band gap (bandwidth of forbidden band). Examples of such compounds include polymers having at least one of the skeletons such as: carbazol, arylamin, fluorenone, and phenanthroline. Particularly, compounds including polymers that have skeletons such as oxadiazole and triazole are preferable. The host moiety including the above skeletons is desirable since those skeletons have particularly large band gaps.

Examples of such host moieties include compounds mentioned above.

One or more substituents may be introduced to these host moieties. Examples of such substituents include, but are not limited to, halogen atoms such as fluorine atom, and linear C6-C12 alkyl.

The host compound in the organic EL layer 15 is effectively applied in the case of using the compounds emitting phosphorescent light, such as the ones expressed in formulae 1-1 through 1-3, as light-emitting moieties contained in the first compound.

The fourth compound may be contained in the organic EL layer 15 without being linked to the random polymers obtained by polymerizing the first compound with at least one of the second and the third compounds. However, the fourth compound may preferably be contained in the organic EL layer 15, as a random copolymer obtained by polymerizing the first, fourth, and at least one of the second and the third compounds.

Therefore, it is preferable that the fourth compound include the fourth polymerizable group linked to the host moiety. Consequently, the random copolymer is obtained in which the first, the fourth, and at least one of the second and the third compounds are polymerized.

The same substituents as that of the first polymerizable group may be used for the fourth polymerizable group.

The number of the fourth polymerizable group that needs to be introduced to the fourth compound is at least one, but preferably more than one. It is desirable that the plurality of fourth polymerizable groups is linked to the host moiety. Consequently, the number of compounds linked to the fourth compound increases. The compounds linking to the fourth compound (host moiety) are: the first compound (light-emitting moiety), the fourth compound (host moiety), and at least one of the second compound (hole transport moiety) and the third compound (electron transport moiety). At the same time, the distances are retained (defined) to a predetermined value, between the light-emitting moiety, the carrier transport moiety, and the host moiety. Thus, the efficiency of implanting the carrier from the carrier transport moiety to the host moiety, as well as the mobility of the excitation energy from the host moiety to the light-emitting moiety increase. Further, the random copolymers, linked so as to form a network, obtain the structure (shape) of a three-dimensional network, and not a linear structure. This improves the heat resistance of the organic EL layer 15, the carrier implantation efficiency from the carrier transport moiety to the host moiety, and the mobility of the excitation energy from the host moiety to the light-emitting moiety.

If the fourth compound contains a plurality of the fourth polymerizable groups, these groups may either be of the same kind (identical) or of a different kind. However, groups of the same kind, identical ones in particular, are preferable. This provides a uniform reactivity among the fourth polymerizable groups, thereby reliably randomizing the linking of the first, fourth, and at least one of the second and the third compounds.

The first through fourth polymerizable groups may either be of the same kind (identical) or of a different kind. However, groups of the same kind, identical ones in particular, are preferable. This provides a uniform reactivity of the first through fourth polymerizable groups, thereby reliably randomizing the first, through fourth compounds.

The combinations of the first through fourth compounds (light-emitting, hole transport, electron transport, and host moieties) included in the random copolymer described above is optionally selected, in accordance with the type of the first compound (light-emitting moiety), so that the organic EL layer 15 exhibits the superior luminous efficiency. Examples of the combinations will be described hereafter.

A: A case where the compound represented by formula 1-1 is selected as the light-emitting moiety.

Compounds represented by formulae 2-5 and/or 2-6, formula 3-2, and formula 1-5, are preferably respectively selected for the hole transport, the electron transport, and the host moieties.

B: A case where the compound represented by formula 1-2 is selected as the light-emitting moiety.

Compounds represented by formula 2-6, formula 3-2 or 4-1, and formula 1-5, are preferably respectively selected for the hole transport, the electron transport, and the host moieties.

C:A case where the compound represented by formula 1-3 is selected as the light-emitting moiety.

Compounds represented by formulae 2-5 and/or 2-6, and formula 3-2, are preferably respectively selected for the hole transport and the electron transport moieties.

D A case where the compound represented by formula 1-4 is selected as the light-emitting moiety.

Compounds represented by formulae 2-5 and/or 2-6, and formula 3-2, are preferably respectively selected for the hole transport and the electron transport moieties.

E: A case where the compound represented by formula 1-5 is selected as the light-emitting moiety.

Compounds represented by formulae 2-5 and/or 2-6, and formula 3-2, are preferably respectively selected for the hole transport and the electron transport moieties.

The preferable range of weight-average molecular weight (Mw) of the random copolymers is, but is not limited to, approximately 10000 to 1000000. Particularly, a range approximately from 15000 to 300000 is preferable. This causes the random copolymers in the organic EL layer 15 to be entangled with each other in a high density, allowing a smooth passing of carriers from the second compound (carrier transport moiety) to the first compound (light-emitting moiety).

The organic EL layer 15 may include low molecular compounds (monomer or oligomer) for the first through third compounds, as long as the light-emitting moiety exhibits superior light-emitting characteristic.

Such random copolymers have the light-emitting moiety and the carrier transport moieties (hole and electron moieties) in a single molecule (polymer), allowing to obtain the organic EL layer 15 having both functions of a light-emitting layer and a carrier transport layer. Therefore, the number of processes for forming the organic EL layer 15 is reduced, allowing to form the organic EL layer 15 in a relatively easy process, improving the manufacturing productivity of the elements. Moreover, characteristic degradation caused by the irregularity between layers is avoided, allowing to obtain a high luminous efficiency.

Further, the light-emitting moiety and the carrier transport moieties (hole transport moiety and/or electron moiety) are linked within a single molecule, thereby reducing a bottleneck of a carrier implantation from the carrier transport moieties to the light-emitting moiety.

In the above description according to one embodiment, the organic EL layer 15 is a single layer, composed with the random copolymers including the first and at least one of the second and the third compounds. However, the composite of the organic EL layer 15 is not limited thereto, and may also include a multilayer structure described hereafter.

Examples of the multilayer structure include composites illustrated in FIGS. 2A through 2G, indicating the light-emitting moiety with a letter “L”, the hole transport moiety with a letter “H”, and the electron transport moiety with a letter “L”, the moieties being included in the polymers (random copolymer or polymer) constituting each layer.

Referring to FIG. 2A, the organic EL layer 15 is a multilayer structure having two layers, where the layer at the anode 13 side is formed with a random copolymer including the hole transport moiety H and the light-emitting moiety L, and the layer at the cathode 14 side is formed with a polymer including the electron transport moiety E.

Referring to FIG. 2B, the organic EL layer 15 is a multilayer structure having two layers, where the layer at the anode 13 side is formed with a polymer including the hole transport moiety H, and the layer at the cathode 14 side is formed with a random copolymer including the electron transport moiety E and the light-emitting moiety L.

Referring to FIG. 2C, the organic EL layer 15 is a multilayer structure having two layers, where the layer at the anode 13 side is formed with a random copolymer including the hole transport moiety H and the light-emitting moiety L, and the layer at the cathode 14 side is formed with a random copolymer including the electron transport moiety E and the light-emitting moiety L.

Referring to FIG. 2D, the organic EL layer 15 is a multilayer structure having three layers, where the layer at the anode 13 side is formed with a polymer including the hole transport moiety H, the layer at the cathode 14 side is formed with a polymer including the electron transport moiety E, and a layer therebetween is formed with a random copolymer including the hole transport moiety H, the electron transport moiety E, and the light-emitting moiety L.

Referring to FIG. 2E, the organic EL layer 15 is a multilayer structure having three layers, where the layer at the anode 13 side is formed with a random copolymer including the hole transport moiety H and the light-emitting moiety L, the layer at the cathode 14 side is formed with a polymer including the electron transport moiety E, and the layer therebetween is formed with a random copolymer including the hole transport moiety H, the electron transport moiety E, and the light-emitting moiety L.

Referring to FIG. 2F, the organic EL layer 15 is a multilayer structure having three layers, where the layer at the anode 13 side is formed with a polymer including the hole transport moiety H, the layer at the cathode 14 side is formed with a random copolymer including the electron transport moiety E and the light-emitting moiety L, and the layer therebetween is formed with a random copolymer including the hole transport moiety H, the electron transport moiety E, and the light-emitting moiety L.

Referring to FIG. 2G, the organic EL layer 15 is a multilayer structure having three layers, where the layer at the anode 13 side is formed with a random copolymer including the hole transport moiety H and the light-emitting moiety L, the layer at the cathode 14 side is formed with a random copolymer including the electron transport moiety E and the light-emitting moiety L, and a layer therebetween is formed with a random copolymer including the hole transport moiety H, the electron transport moiety E, and the light-emitting moiety L.

Referring back to FIGS. 2A to 2G, the organic EL layer 15 is formed in multilayer, and each layer of the multilayer structure is composed with a random copolymer or a polymer. This improves durability (or solvent resistance) of each layer. Without the above, the solvent or dispersion medium included in the liquid material for forming the upper layer may cause swelling or dissolution of the polymers contained in the lower layer. As a result, even if the liquid material is deposited on the lower layer so as to form the upper layer, such swelling or dissolution is suppressed or prevented. Consequently, phase solubility between the upper and the lower layers is prevented in a high reliability.

The preferable range for the average thickness of such organic EL layer 15 includes, but is not limited to, approximately 10 to 300 nm. Particularly, a range approximately from 50 to 150 nm is preferable.

The light-emitting element 11 may be provided with the hole transport layer having a function to transport holes between the organic EL layer 15 and the anode 13, or, may be provided with the electron transport layer having a function to transport electrons between the organic EL layer 15 and the cathode 14.

Examples of constituent materials of the hole transport layer include: polyethylene dioxythiophene -polystyrene sulfonate, polyaniline-polystyrene sulfonate, polyarylamine, fluorene-arylamine copolymer, fluorene-bithiophene copolymer, poly(N-vinylcarbazole), polyvinylpyrene, polyvinylanthracene, polythiophene, polyalkylthiophene, polyhexylthiophene, poly(p-phenylenevinylene), polythienylenevinylene, pyrene formaldehyde resin, ethylcarbazole formaldehyde resin, and their derivatives. These materials may be used alone or in combination of two or more.

Examples of constituent materials of the electron transport layer include: benzene-based compounds such as 1,3,5-tris[(3-phenyl-6-tri-fluoromethyl)quinoxaline-2-yl]benzene (TPQ1), naphthalene compounds, phenanthrene compounds, chrysene compounds, perylene compounds, anthracene compounds, pyrene compounds, acridine compounds, stilbene compounds, thiophene compounds such as BBOT, butadiene compounds, coumarin compounds, quinoline compounds, bistyryl compounds, pyrazine compounds such as distyrylpyrazine, quinoxaline compounds, benzoquinone compounds such as 2,5 -diphenyl-para-benzoquinone, naphthoquinone compounds, anthraquinone compounds, oxadiazole compounds such as 2-(4-biphenylyl)-5-(4-t-butylphenyl)-1,3,4-oxadiazole (PBD), triazole compounds such as 3,4,5-triphenyl-1,2,4-triazole, oxazole compounds, anthrone compounds, fluorenone compounds such as 1,3,8-trinitro-fluorenone (TNF), diphenoquinone compounds such as MBDQ, stilbenequinone compounds such as MBSQ, anthraquinodimethane compounds, thiopyran dioxide compounds, fluorenylidenemethane, diphenyldicyanoethylene compounds, florene compounds, pyrrole compounds, phosphine oxide compound, various metal complexes such as 8-hydroxyquinoline aluminum (Alq₃), and, finally, complexes having benzooxazole or benzothiazole as a ligand. These materials may be used alone or in combination of two or more.

The sealer 16 is disposed so as to cover the light-emitting element 11 (the anode 13, the organic EL layer 15, and the cathode 14), and is provided with a function to seal the element airtight, keeping out the oxygen or moisture caused by an ambient air. The sealer 16 provides positive effects such as a reliability improvement of, as well as a prevention of deterioration or degradation (durability improvement) of the light-emitting element 11.

Examples of constituent materials of the sealer 16 include: various glass materials; Al, Au, Cr, Nb, Ta, Ti, and alloys containing them; silicon oxide; and various resins. In case of using the conductive materials for the sealer 16, an insulation film may preferably be provided between the sealer 16 and the light-emitting element 11 if necessary, in order to prevent a short circulation.

The sealer 16 may take a form of a flat plate facing the substrate 12, and can seal between the plate and the substrate with a sealer such as thermosetting resin,

Manufacturing Method of Light-Emitting Element

Examples of a method for manufacturing the light-emitting element 11 in accordance with a method for manufacturing a light-emitting element according to one embodiment of the invention will now be described.

A method for manufacturing the light-emitting element 11 (a method for manufacturing a light-emitting element according to one embodiment of the invention) will now be described.

1. Anode Forming Process

The substrate 12 is prepared, and the anode 13 is formed thereon.

Examples of methods for forming the anode 13 include: chemical vapor depositions such as plasma enhanced CVD, thermal CVD, laser assisted CVD; dry plating such as vacuum evaporation, sputtering, and ion plating; wet plating such as electrolysis plating, dip plating, and electroless plating; thermal spray, sol gel, metal-organic deposition, and adhering metallic foil.

2. Organic EL Layer Forming Process

The organic EL layer 15 is then formed on the anode 13.

There is an advantage in a method for forming this organic EL layer 15 in accordance with a method for manufacturing a light-emitting element according to one embodiment of the invention.

As described in the “Related Art” section, it has been known that an organic EL layer into which block copolymers are synthesized in advance, would also exhibit a good light-emitting characteristic. Unfortunately, synthesizing such block copolymers requires numerous processes, and the synthesized block copolymers have a low yield.

As a result of the inventor's keen examination to enable an organic EL layer to be formed in a single layer without using block copolymers, the inventor found out that an organic EL layer can be made light emissive, by forming the organic EL layer with random copolymers, instead of block copolymers.

However, if an organic EL layer were formed by the following method, a superior light-emitting characteristic would unfortunately not be obtained, because of an insufficient density of the entanglement of the random copolymers included in the layer. The method included: preparing liquid material, having synthesized random copolymers dissolved therein, thereafter supplying the liquid material on an anode, and drying.

The inventor further examined the composite obtained by forming random copolymers on an anode. In this composite, a luminescent monomer (the first compound) and a carrier transporting monomer (the second and/or third compounds) were supplied on the anode (the first electrodes. These monomers were then polymerized so as to form a random copolymer on this anode. As a result, an organic EL layer was formed with high-density random copolymers, densely cross-linked in three-dimensions. The inventor found out that it is possible for an organic EL layer to exhibit a superior light-emitting characteristic, and thus the present invention has been completed.

A method for forming this organic EL layer 15 will now be described in detail.

3-1. The film including the first and at least one of the second and the third compounds is formed (a first process) on the anode 13 (a first electrode).

This coating is formed with various processes such as a liquid phase process or a vapor phase process, but preferably with a liquid phase process.

This is because the liquid phase process allows a depositing of coating in a relatively simple process, without using large-scale devices such as a vacuum system, by providing the anode 13 with liquid material that includes the first compound as well as at least one of the second compound and the third compound.

An example of forming the film on the anode 13 with the liquid phase process will now be described.

The film is formed by supplying liquid material including the first and at least one of the second and the third compounds on the anode 13.

In this coating, the preferable range of weight ratios is from 1:100 to 90:10, representing the weight ratio of the first compound (emissive monomer) to the sum of the second and the third compounds (carrier transporting monomer). However, this range may change significantly, depending on the type of compounds used for the first compound (light-emitting moiety), the second compound (hole transport moiety), and the third compound (electron transport moiety). This way, in the organic EL layer 15 formed, the carrier transport moiety supplies the carriers implanted from the electrode to the light-emitting moiety with a high reliability.

Various coating methods may be used, such as: spin coating, casting, microgravure coating, gravure coating, barcode, roll coating, wire barcode, dip coating, spray coating, screen printing, flexo printing, offset printing, and inkjet printing. Such coating method allows to easily supply the liquid material to the anode 13.

The solvent or dispersion medium to prepare the liquid material may be organic or inorganic solvents, or mixed solvents containing them. Examples of the inorganic solvents may include: nitric acid, sulfuric acid, ammonia, hydrogen peroxide, water, carbon disulfide, carbon tetrachloride, and ethylene carbonate. Examples of the organic solvents may include: ketone solvents such as methyl ethyl ketone (MEK), acetone, diethyl ketone, methyl isobutyl ketone (MIBK), methyl isopropyl ketone (MIPK), cyclohexanone; alcohol solvents such as methanol, ethanol, isopropanol, ethylene glycol, diethylene glycol (DEG), glycerine; ether solvents such as diethyl ether, diisopropyl ether, 1,2-dimetoxyethane (DME), 1,4-dioxane, tetrahydrofuran (THF), tetrahydropyran (THP), anisole, diethylene glycol dimethyl ether (diglyme), diethylene glycol ethyl ether (carbitol); cellosolve solvents such as methyl cellosolve, ethyl cellosolve, phenyl cellosolve; aliphatic hydrocarbon solvents such as hexane, pentane, heptane, cyclohexane; aromatic hydrocarbon solvents such as toluene, xylene, benzene; aromatic heterocyclic compound solvents such as pyridine, pyrazine, furan, pyrrole, thiophene, methylpyrrolidone; amide solvents such as N,N-dimethylformamide (DMF), N,N-dimethylacetamide (DMA); halogenated compound solvents such as chlorobenzene, dichloromethane, chloroform, 1,2-dichloroethane; ester solvents such as ethyl acetate, methyl acetate, ethyl formate; sulfur compound solvents such as dimethylsulfoxide (DMSO), sulfolane; nitrile solvents such as acetonitrile, propionitrile, acrylonitrile, organic acid solvents such as formic acid, acetic acid, trichloroacetic acid, trifluoroacetic acid.

It is preferable that the liquid material contain a polymerization initiator. This promote polymerization of the first compound as well as at least one of the second and the third compound in the proceeding process 3-2 in which treatments such as heating and light irradiations are carried out.

Examples of polymerization initiator include, but are not limited to, photopolymerization initiators such as a cationic photopolymerization initiator and a photoradical polymerization initiator, a thermal polymerization initiator, and an anaerobic polymerization initiator.

The first through third polymerizable groups (which hereafter may also collectively be called “polymerizable groups”) are preferably, as described, of the same kind (in particular, identical). If radical polymerizable groups are selected, a photoradical polymerization initiator is particularly desirable as an initiator. Such groups are terminated with, for instance, (meth)acryloyls, vinylbenzyl ethers, and allyls.

Examples of photo-radical polymerization initiator include initiators such as: benzophenones, benzoins, acetophenones, benzyl ketals, Michler's ketones, acyl phosphine oxides, ketocoumarins, xanthones, and thioxanthones.

The cationic photopolymerization initiator is particularly desirable in the case of selecting the polymerizable groups terminated with cation polymerizable groups (in other words, the polymerizable groups terminated with, for instance, epoxies, oxetanes, and vinyl ethers).

Examples of photo cation polymerization initiator include onium salts such as aromatic sulfonium salts, aromatic iodonium salts, aromatic diazonium salts, pyridium salts, and aromatic phosphonium salts; and nonionics such as an iron arene complex and sulfonic ester.

The polymerization of the first as well as at least one of the second and the third compounds can be made to progress relatively easily in the proceeding process 3-2, by optionally selecting a suitable polymerization initiator described above.

In the case of using the photopolymerization initiator, sensitizer suitable for the photopolymerization initiator may also be added to the liquid material.

3-2. Subsequently, the organic EL layer 15 (light-emitting layer) is obtained as a result of polymerizing, in the film formed on the anode 13, the first compound as well as at least one of the second and the third compounds (a second process).

Various treatments may be used to polymerize the first as well as at least one of the second and the third compounds. Examples of treatments include a light irradiation treatment directing light on the film, a thermal treatment heating the film, and an anaerobic treatment blocking the contact between gas and the film. Among these, the thermal and light irradiation treatments are preferable (in particular, the light irradiation). This is because the thermal and light irradiation treatments allow a relatively easy control over the reaction speed of polymerization. Particularly, the light irradiation treatment is preferable, since it provides a high degree of selectivity in polymerization region.

Examples of light beams irradiated to the film include infrared light, visible light, ultraviolet light, and X-ray. These light beams may be used alone or in combination of two or more. Particularly, the ultraviolet light is preferable. The polymerization of the first and of at least one of the second and the third compounds thereby proceeds reliably and easily.

The preferable wavelength range of the ultraviolet light used for the light irradiation is approximately from 100 to 420 nm. Particularly, a range approximately from 150 to 400 is preferable.

The preferable wavelength range of the ultraviolet light used for light irradiation is approximately from 1 to 600 mW/cm². Particularly, a range approximately from ] to 300 mW/cm² is preferable.

The preferable irradiation time of the ultraviolet light is approximately from 10 to 900 seconds. Particularly, duration approximately from 10 to 600 seconds is preferable.

The polymerization progress of the first and the second compounds in the film is relatively easily controlled by setting the wavelength, irradiation intensity and irradiation time of ultraviolet light to above ranges.

4. Cathode Forming Process

The cathode 14 is then formed on the organic EL layer 15, on the opposite side of the anode 13 (a third process).

The cathode 14 may be formed using methods such as vacuum deposition, sputtering, adhering metallic foil, coating and baking of metallic powder ink.

5. Sealer Forming Process

Finally, the sealer 16 is adhered to the substrate 12, so as to cover the anode 13, the organic EL layer 15, and the cathode 14.

The light-emitting element 11 is manufactured through the above processes.

The above-described method for manufacturing the light-emitting element 11 does not require any large-scale equipment such as a vacuum device for forming the organic EL layer 15. This also applies to the case of using the metallic powder ink for forming the cathode. Thus, the production time and the manufacturing cost are reduced.

The random copolymers constituting the organic EL layer 15 is provided with functions to emit light as well as to transport the carrier, therefore allowing the organic EL layer 15 to expose its functionality as a light-emitting layer as well as a carrier transport layer in a single layer. Therefore, the number of processes for manufacturing the light-emitting element 11 is reduced, allowing a formation of the organic EL layer 15 in a relatively easy process, improving the manufacturing productivity of the elements.

A light source is one example of the application of the light-emitting element 11 manufactured with the method for manufacturing a light-emitting device according to one embodiment of the present invention. A display device may be formed using the plurality of light-emitting elements 11, by disposing them in matrix.

Such display device may be driven in either the active-matrix system or the passive-matrix system, and does not have a specific limitation as to how it is driven.

Light-Emitting Device

A display device will now be described as an example of the light-emitting device provided with the above-referenced light-emitting elements.

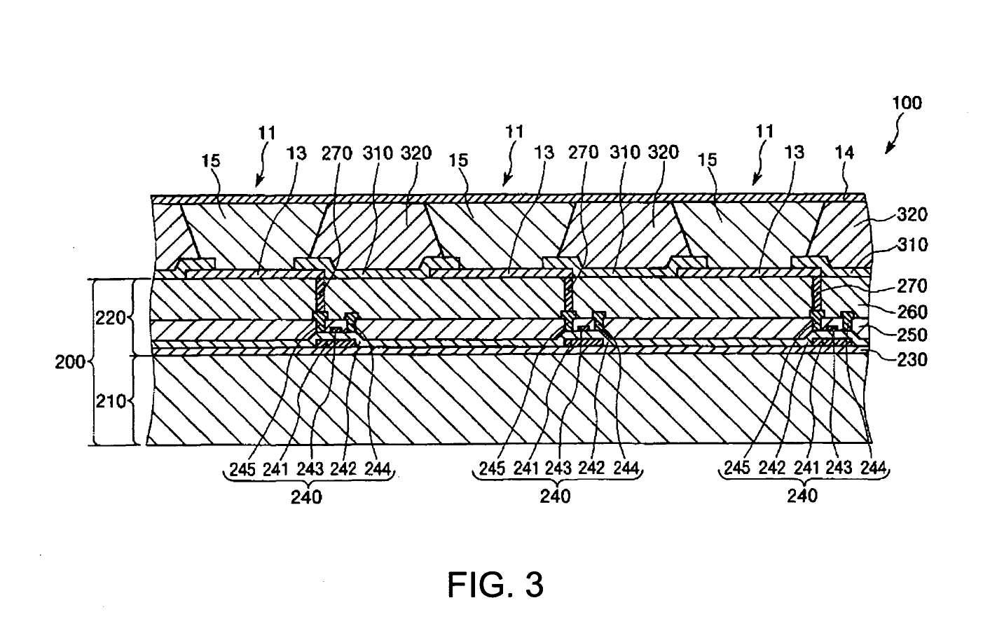

FIG. 3 is a cross-sectional view of a display device provided with a light-emitting element.

A display device 100 includes a body 200 and a plurality of light-emitting elements 11 installed on the body 200.

The body 200 includes a substrate 210 and a circuit unit 220 formed on this substrate 210.

The circuit unit 220 includes a protection layer 230 formed on the substrate 210, driving TFTs (switching elements) 240, a first insulating interlayer 250, and a second insulating interlayer 260. Here, the protection layer 230 is composed of, for instance, silicon oxide.

Each of the driving TFTs 240 includes a semiconductor layer 241 composed of silicon, a gate insulating layer 242 formed on the semiconductor layer 241, a gate electrode 243, a source electrode 244, and a drain electrode 245.

Each of the light-emitting elements 11 is installed above the circuit unit 220, corresponding to each of the driving TFTs 240. The adjacent light-emitting elements 11 are partitioned by a first partition wall 310 and a second partition wall 320.

The anode 13 in the light-emitting element 11 constitutes a pixel electrode, electrically connected to the drain electrode 245 in each of the driving TFTs 240 through a wiring 270. The cathode 14 in the light-emitting element 11 is a common electrode.

The un-illustrated sealer is adhered to the body 200, so as to cover and seal the light-emitting element 11.

The display device 100 may be monochromatic. A color display is also possible with random copolymers that have different kinds of light-emitting moieties.

Such display device 100 may be implemented to various electronic apparatuses.

The previously described method for manufacturing a light-emitting element needs to be included in the method for manufacturing the above display device (light-emitting device).

Electronic Apparatus

Hereafter, an example of an electronic apparatus provided with the light-emitting device referenced above will be described,

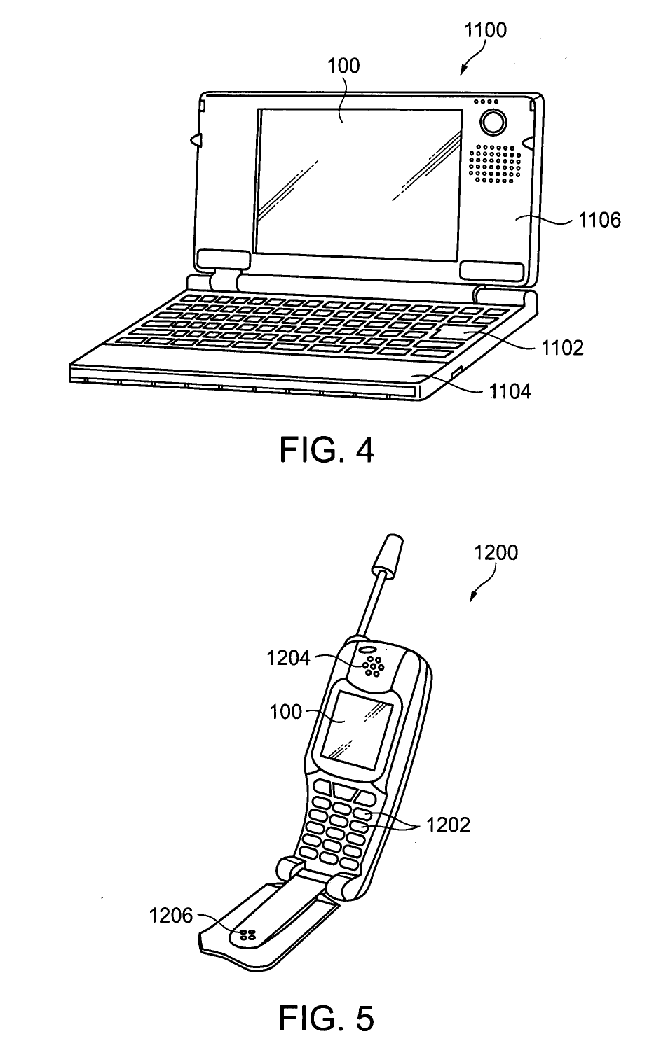

FIG. 4 is a perspective view of a mobile (or notebook) personal computer provided with a light-emitting device.

In this drawing, a personal computer 1100 includes a body 1104 provided with a keyboard 1102, and a display unit 1106 provided with a display. The display unit 1106 is supported so that it can pivot on the body 1104 with a hinge.

The display included in the display unit 1106 of the personal computer 1100 is formed with the aforementioned display device 100.

FIG. 5 is a perspective view of a mobile phone, including a personal handy-phone system (PHS), provided with a light-emitting device.

A mobile phone 1200 in this drawing is provided with a display, along with a plurality of operation buttons 1202, an earpiece 1204, and a mouthpiece 1206.

This display is formed with the display device 100 described above in the mobile phone 1200.

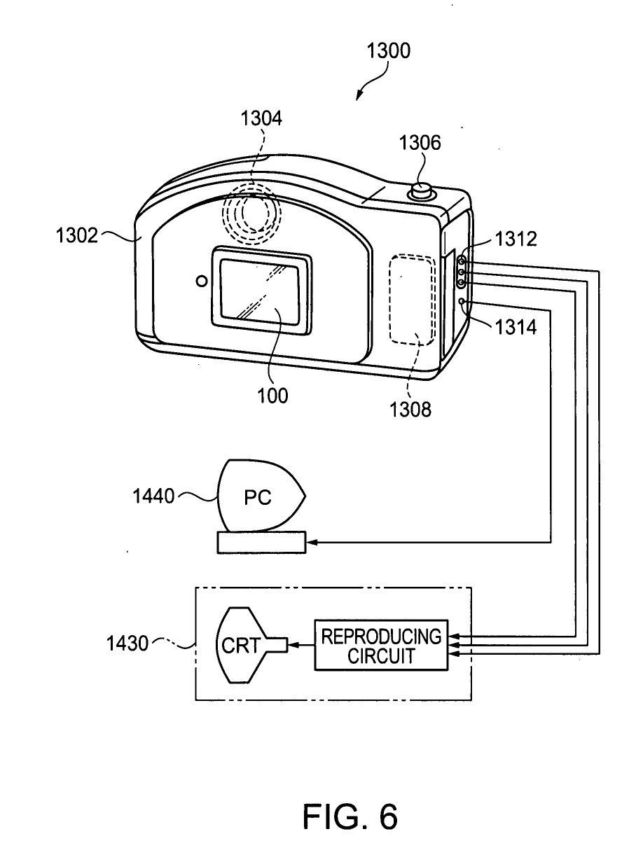

FIG. 6 is a perspective view of a digital still camera provided with a light-emitting device. This drawing also briefly illustrates the connection with external apparatuses.

While a traditional analog camera exposes a silver halide photographic film to a light figure of a subject, a digital still camera 1300 performs photoelectronic conversion of the light figure of the subject by image sensors such as charge coupled device (CCD), and generates imaging signals (image signals).

A display is provided to the back of a case (body) 1302 of the digital still camera 1300. The display serves as a finder, displaying the subject as an electronic image, based on the imaging signals from the CCD.

The display device 100 described above is included in this display of the digital still camera 1300.

A circuit substrate 1308 is installed inside the case. A memory for storing (retaining) the imaging signals is installed on this circuit substrate 1308.

A light receiving unit 1304 is installed on the front side of the case 1302 (in the drawing, the back side), including components such as optical lens (optical imaging system) and CCD.

If a photographer confirms the subject in the display and presses a shutter button 1306, the imaging signal of the CCD of that moment is transferred and stored to the memory of the circuit substrate 1308.

This digital still camera is provided with a video signal output terminal 1312 and a data communication input-output terminal 1314, at the side of the case 1302. As shown in the drawing, a television monitor 1430 and a personal computer 1440 are respectively connected, as needed, to the video signal output terminal 1312 and the input-output terminal 1314. Imaging signals stored in the memory of the circuit substrate 1308 is output to the television monitor 1430 or a personal computer 1440 by a predetermined operation.

The electronic apparatus provided with the light-emitting device may be applied to: the personal computer (mobile PC) shown in FIG. 4, the mobile phone shown in FIG. 5, the digital still camera shown in FIG. 6. Other examples of such apparatuses include: televisions, video cameras, video tape recorders of the viewfinder type or the direct viewing monitor type, laptop personal computers, car navigation devices, pagers, electronic notebooks (including the ones with communication function), electronic dictionaries, electric calculators, electronic gaming apparatuses, word processors, workstations, video phones, security TV monitors, electronic binoculars, POS terminals, devices incorporating touch panels such as cash dispensers of financial institutions and ticketing machines, medical apparatuses such as electronic thermometer, hemadynamometer, glycemia, electrocardiographic display devices, ultrasound devices, display devices for endoscopes, fish detectors, various measuring instrument, gauges such as for vehicles, airplanes and ships, flight simulators, other various monitors, and projector display devices.

The method for manufacturing the previously described light-emitting device (light- emitting element) needs to be included in the method for manufacturing these electronic apparatuses.

The method for manufacturing the light-emitting element, the light-emitting device, and the electronic apparatus has been described based on the embodiment referred to in the drawings. However, the present invention is not limited thereto.

### EXAMPLES

Specific examples related to the embodiments of the invention will now be described.

1. Synthesis of Compounds

The following compounds were synthesized.

### Synthesis of Polymerizable Iridium Complex (A1) Represented by Formula 5-1

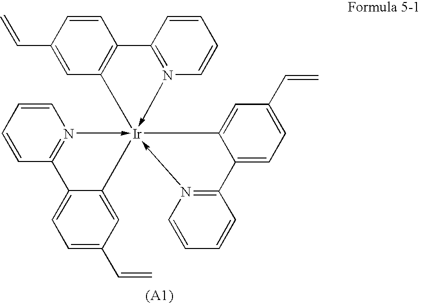

A polymerizable iridium complex (A1) is a compound that emits green light.

First, 2-(4-vinylphenyl)pyridine (A11) was synthesized using a synthetic route represented in formula 5-2 attached below.

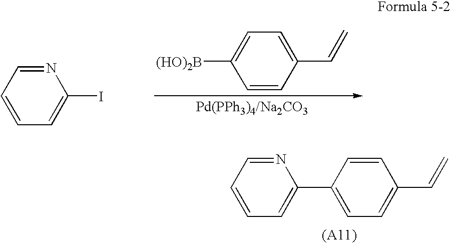

Tetrakis(triphenylphosphine)palladium(0) (1 mmol) and 4-vinylphenylboronic acid (10 mmol:Tokyo Chemical Industry Co., Ltd) were added to the xylene solution of 2-iodo-pyridine (10 mmol), and were stirred.

Thereafter, sodium bicarbonate solution was added to the mixed solution described above in a nitrogen atmosphere, and the solution was heated to reflux for 12 hours.

Subsequently, methylene chloride/water was added to this reactive mixture, so as to extract an aqueous layer using methylene chloride.

The recovered organic layer was then dried with anhydrous magnesium sulfate, and the solvent thereof was removed in vacuum concentration. The deposited solid was recrystallized with xylene, and 2-(4-vinylphenyl)pyridine (A11) was obtained (yield 65%).

Thereafter, the polymerizable iridium complex (2-(4-vinylphenyl)pyridine-iridium complex) (A1) was synthesized using a synthetic route represented in formula 5-3 attached below.

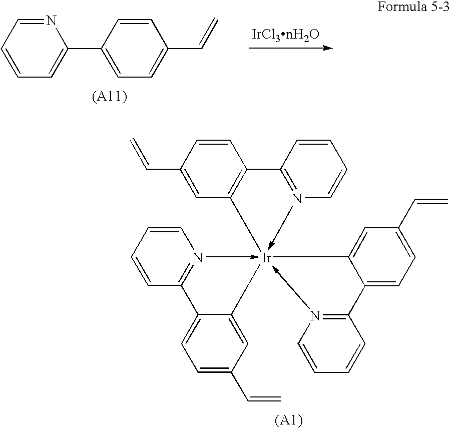

Iridium trichloride (III) hydrate (300 mg) and 2-(4-vinylphenyl)pyridine (A11) synthesized in the previous procedures (4.5 g, 25 mmol) were added to the ethylene glycol (40 mL), bubbling nitrogen through this mixed solution.

Thereafter, this mixed solution was heated to reflux for 6 hours in the nitrogen stream, using a mantle heater.

This reactive solution was then cooled down to room temperature, and filtered to isolate the deposited solid. This deposited solid was washed, first with water and then with xylene, and then dried under reduced pressure; thereby the polymerizable iridium complex (A1) was obtained (yield 48%).

Confirmation of the obtained polymerizable iridium complex (A1) was performed using devices such as Proton Nuclear Magnetic Resonance (¹H NMR) and Fourier Transform infrared Spectrometer (FT-IR).

### Synthesis of Polymerizable Iridium Complex (A2) Represented by Formula 6-1

A polymerizable iridium complex (A2) is a compound that emits green light.

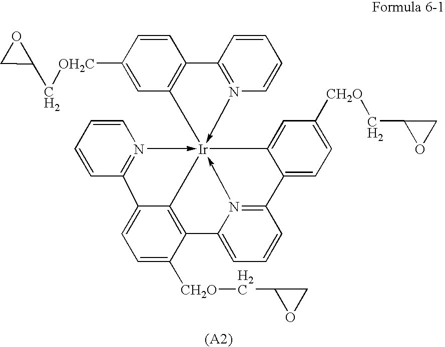

First, a benzyl ether boronic acid derivative (A23) was synthesized using a synthetic route represented in formula 6-2 attached below.

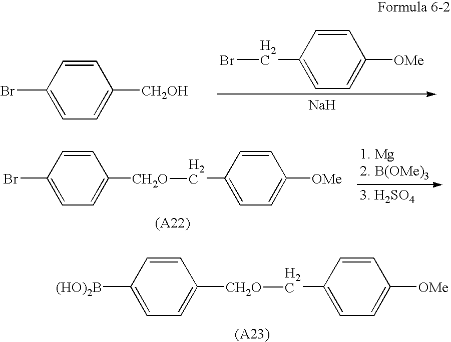

4-bromobenzyl alcohol (1 mol) was processed in anhydrous dimethylformamide with 4-methoxybenzyl bromide and sodium hydroxide, so as to convert a hydroxyl group into a 4-methoxybenzyl ether group, obtaining a 4-bromo-benzyl ether derivative (A22).

Thereafter, the 4-bromo-benzyl ether derivative (A22) synthesized in the previous procedure (15 mmol) and metallic magnesium (20 mmol) were dissolved into anhydrous THF, so as to prepare a Grignard reagent.

Anhydrous THF of trimethoxyboronic acid (15 mmol) was then dripped slowly into this reactive mixture kept at −15° C. in a nitrogen atmosphere, and the solution was stirred for 1 hour at the same temperature.

A sulfuric acid solution (10 g, 10%) was added into this reactive mixture, and the mixture was stirred for 24 hours while bringing the temperature back to room temperature.

Subsequently, THF was removed from this reactive mixture in a reduced pressure, and pure water/ether was added thereto, so as to extract an aqueous layer using ether.

Anhydrous magnesium sulfate was added to the recovered organic layer, and the layer was dried. The solvent was then removed in a vacuum concentration. The deposited solid was recrystallized with xylene, and thus the benzyl ether boronic acid derivative (A23) was obtained (yield 60%).

Confirmation of the obtained benzyl ether boronic acid derivative (A23) was performed using devices such as ¹H NMR and FT-IR.

Thereafter, 2-(4-(4-methoxybenzyloxy)methylphenyl)pyridine (A21) was synthesized using a synthetic route represented in formula 6-3 attached below.

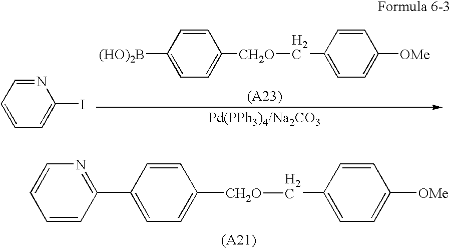

Tetrakis(triphenylphosphine)palladium(0) (1 mmol) and the benzyl ether boronic acid derivative (A23) synthesized in the above procedure (10 mmol) were added to the xylene solution of 2-iodo-pyridine (10 mmol), and the solution was stirred.

Thereafter, sodium bicarbonate solution was added to the mixed solution described above in nitrogen atmosphere, and the mixed solution was heated to reflux for 15 hours.

Subsequently, methylene chloride/water was added to this reactive mixture, so as to extract an aqueous layer using methylene chloride.

The recovered organic layer was then dried with anhydrous magnesium sulfate, and the solvent thereof was removed in vacuum concentration. The deposited solid was recrystallized with xylene, and 2-(4-(4-methoxybenzyloxy)methylphenyl)pyridine (A21) was thereby obtained (yield 58%).

Subsequently, an iridium complex (A24) was synthesized using the synthetic route represented in formula 6-4 attached below.

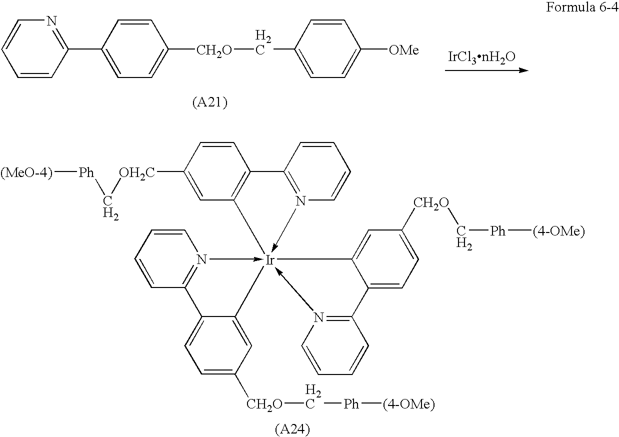

Iridium trichloride (III) hydrate (30 mg) and pyridine derivative (A21) synthesized in the previous procedures (6.9 g, 25 mmol) were added to the ethylene glycol (50 mL), and nitrogen was bubbled through this mixed solution.

Thereafter, this mixed solution was heated to reflux in a nitrogen stream for 6 hours, using a mantle heater.

This reactive solution was then cooled down to room temperature, and was filtered to isolate the deposited solid. This deposited solid was washed, first with water and then with xylene, and was dried under a reduced pressure, thereby obtaining the iridium complex (A24).

Thereafter, the polymerizable iridium complex (2-(4-(glycidyloxymethyl)phenyl)pyridine-iridium complex) (A2) was synthesized using a synthetic route represented in formula 6-5 attached below.

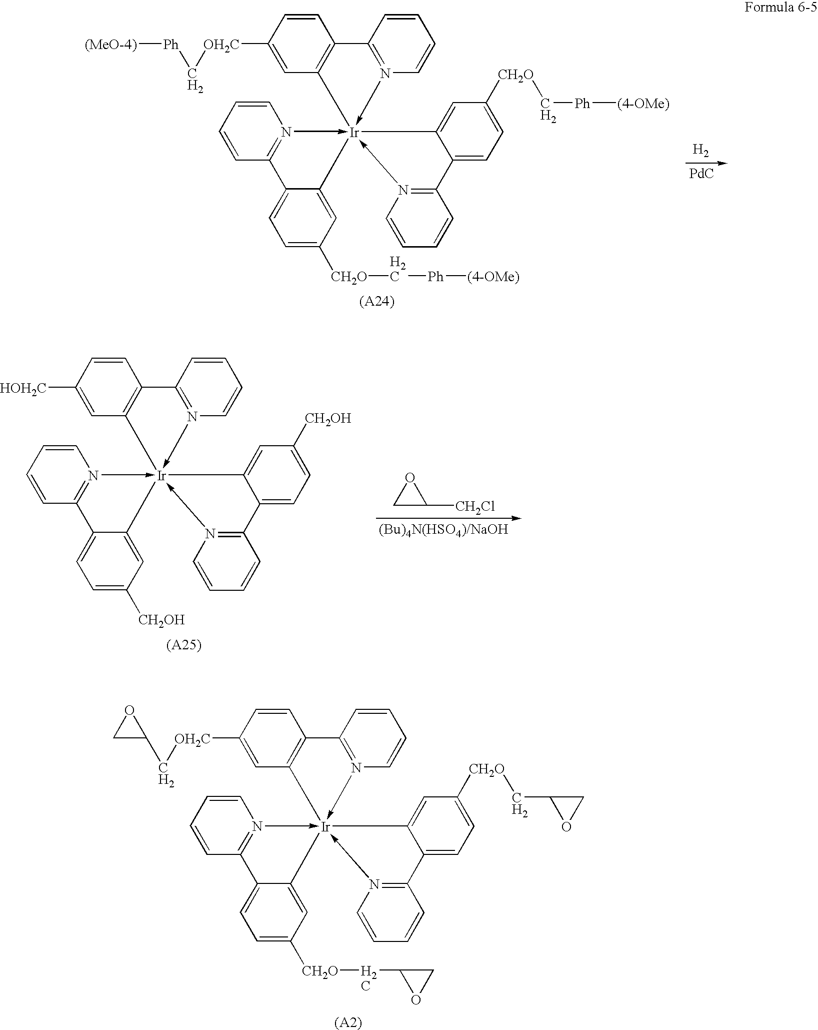

First, the resultant iridium complex (A24) (10 mmol) and palladium-carbon 0.5 g were added to the mixed solution of xylene/ethyl acetate (150 mL). After a hydrogen reduction in nitrogen atmosphere, deprotection of a benzyl group was carried out, so as to obtain a 2-(4-(hydroxymethyl)phenyl)pyridine-iridium complex (A25).

This reactive solution was added to a 50% sodium hydroxide solution containing epichlorohydrin (30 g) and a small amount of tetrabutylammonium hydrogen sulfate salt (phase-transfer catalyst). This solution was stirred for 12 hours at room temperature.

Subsequently, the solids in the reactive mixture was filtered out, and was purified several times with xylene/methanol, thereby obtaining the polymerizable iridium complex (A2).

Confirmation of the obtained polymerizable iridium complex (A2) was performed using devices such as ¹H NMR and FT-IR.

### Synthesis of Polymerizable Iridium Complex (A3) Represented by Formula 7

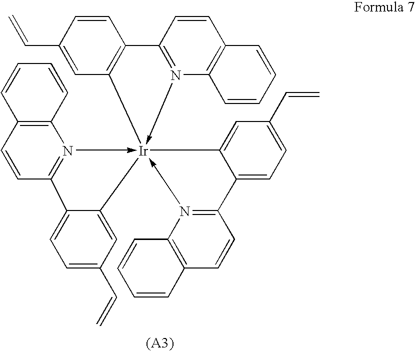

A polymerizable iridium complex (A3) is a compound that emits red light.

The synthetic route of this polymerizable iridium complex (2-(4-vinylphenyl)quinoline-iridium complex) (A3) was similar to that of the polymerizable iridium complex (A1), except for using 2-chloroquinoline instead of 2-iodo-pyridine.

Confirmation of the obtained polymerizable iridium complex (A3) was performed using devices such as ¹H NMR and FT-IR.

### Synthesis of Polymerizable Iridium Complex (A4) Represented by Formula 8

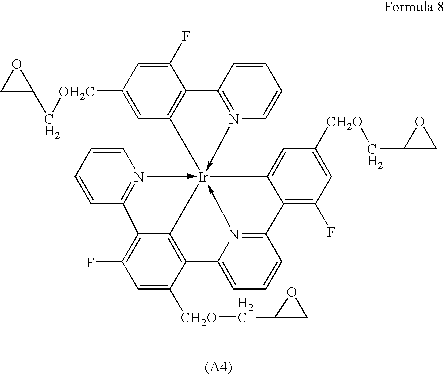

A polymerizable iridium complex (A4) is a compound that emits blue light.

The synthetic route of this polymerizable iridium complex (2-(2-fluoro-4-glycidyloxymethylphenyl)pyridine iridium complex) (A4) was similar to that of the polymerizable iridium complex (A2), except for using 4-bromobenzyl alcohol instead of 4-bromo-2-fluorobenzyl bromide.

Confirmation of the obtained polymerizable iridium complex (A4) was performed using devices such as ¹H NMR and FT-IR.

### Synthesis of Polymerizable Iridium Complex (A5) Represented by Formula 9-1

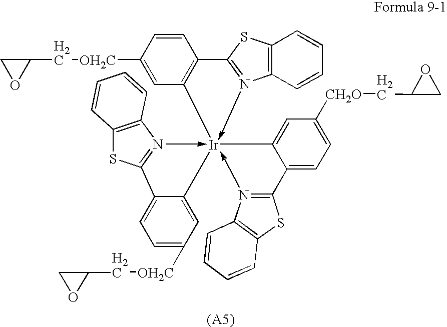

A polymerizable iridium complex (A5) is a compound that emits red light.

First, 2-(4-benzyloxymethylphenyl)-1,3-benzothiazole (A51) was synthesized using a synthetic route represented in formula 9-2 attached below.

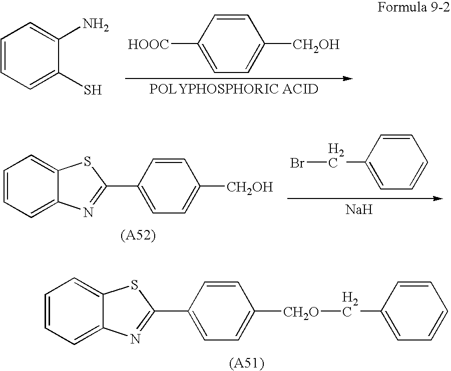

4-hydroxymethylbenzoic acid (10 mmol) and 2-aminothiophenol (10 mmol) were added to polyphosphoric acid (50 g), and the mix was stirred vigorously.

Thereafter, this mixed solution was heated up to 250° C., and was stirred in that temperature for 4 hours.

Subsequently, the reactive solution was cooled down to 100° C., and a large amount of pure water was poured therein, while being stirred.

The deposited solid was filtered and washed with a small amount of water. The solid was stirred again in 10% sodium carbonate solution, filtered, and washed with pure water until the filtrate became neutral, and thereafter was dried to obtain 2-(4-hydroxymethylphenyl)-1,3-benzothiazole (A52).

Thereafter, the compound A52 obtained in the above procedure was processed with benzyl bromide and sodium hydroxide in anhydrous dimethylformamide, so as to protect the hydroxyl group with the benzyl group, converting the hydroxyl group to a benzyl ether group, thereby obtaining 2-(4-benzyloxymethylphenyl)-1,3-benzothiazole (A51).

Subsequently, the polymerizable iridium complex (2-(4-glycidyloxymethylphenyl)-1,3-benzothiazole-iridium complex) (A5) was synthesized using the similar synthetic route represented in formulae 6-4 and 6-5 referred above.

Confirmation of the obtained polymerizable iridium complex (A5) was performed using devices such as ¹H NMR and FT-IR.

### Synthesis of Polymerizable Iridium Complex (A6) Represented by Formula 10-1

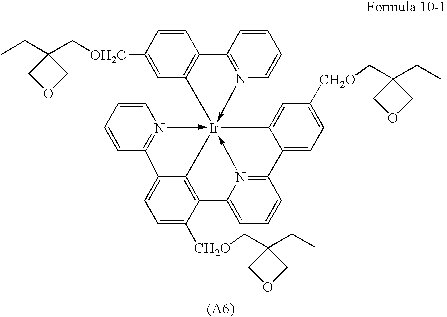

A polymerizable iridium complex (A6) is a compound that emits green light.

First, 2-(4-(hydroxymethyl)phenyl)pyridine-iridium complex (A25) was synthesized using the synthetic route represented in formulae 6-1 to 8 referred above.

Thereafter, the polymerizable iridium complex (2-(4-(2-oxetanylbutyloxymethyl)phenyl)pyridine-iridium complex) (A6) was synthesized using a synthetic route represented in formula 10-2 attached below.

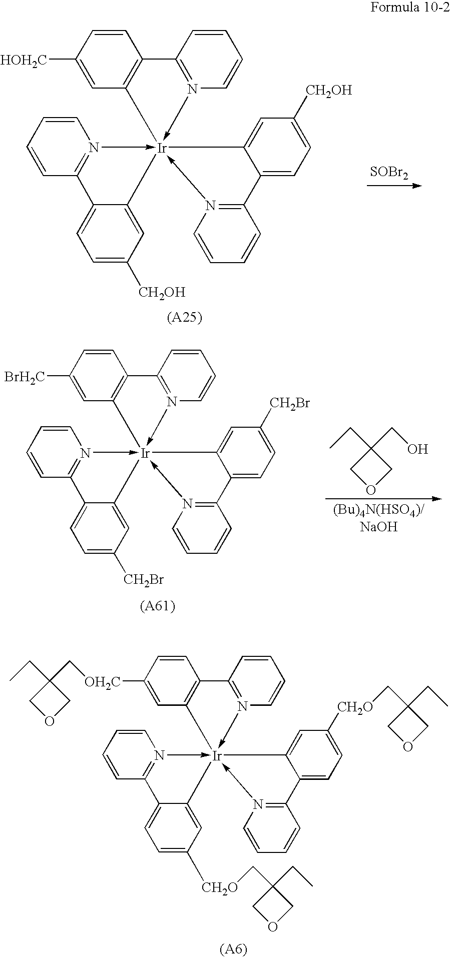

2-(4-(hydroxymethyl)phenyl)pyridine-iridium complex (A25) synthesized in the above procedures and thionyl bromide were mixed together. This mixed solution was heated so as to obtain a 2-(4-(bromomethyl)phenyl)pyridine-iridium complex (A61).

This reactive solution was added to 50% sodium hydroxide solution containing 3-ethyl-3-hydroxymethyloxetane and a small amount of tetrabutylammonium hydrogen sulfate salt (phase-transfer catalyst), and was stirred for 12 hours at room temperature.

Subsequently, the solids in the reactive mixture was filtered out, purified several times with xylene/methanol, and polymerizable iridium complex (A6) was obtained.

Confirmation of the obtained polymerizable iridium complex (A6) was performed using devices such as ¹H NMR and FT-IR.

### Synthesis of Polymerizable Aluminium Complex (A7) Represented by Formula 11-1

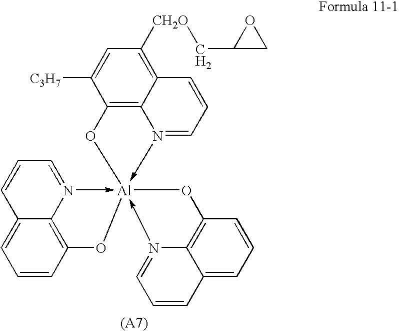

A polymerizable iridium complex (A7) is a compound that emits green light.

First, 5 -hydroxymethyl-7-propylquinolinol (A71) was synthesized using a synthetic route represented in formula 11-2 attached below.

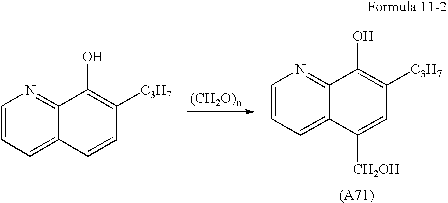

7-propyl-8-quinolinol (20 mmol) and paraformaldebyde (0.75 g) were added to a mixed solution of 1,2-dimethoxyethane/xylene (100 mL), and the solution was stirred.

Thereafter, this mixed solution was heated to reflux for 12 hours at 135° C.

After cooling down this reactive mixture to room temperature, methanol was added to the mix. The deposited solid was filtered, washed with a small amount of xylene, isolated and purified with silica gel column chromatography (methanol:dichloromethane=3:97), thereby obtaining 5-hydroxymethyl-7 -propylquinolinol (A71) (yield 23%).

At the same time, an aluminum complex (A72) was synthesized using a synthetic route represented in formula 11-3 attached below.

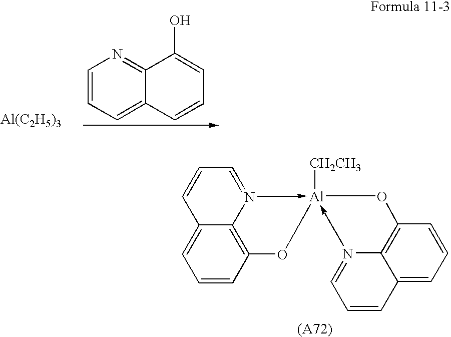

Toluene solution (100 mL) of 8-quinolinol (72 mmol) was dripped into the toluene solution of 25 wt % triethylaluminum (20 mL; 36 mmol) for 1 hour at room temperature.

Subsequently, the solution was stirred for 12 hours at room temperature, and the precipitated solid was filtered out. The filtrate was vacuum concentrated, and the deposited solid was washed with a small amount of toluene, thereby obtaining aluminum complex (A72) (yield 95%).

Thereafter, an alcohol (A73) of the aluminum complex was synthesized using a synthetic route represented in formula 11-4 attached below.

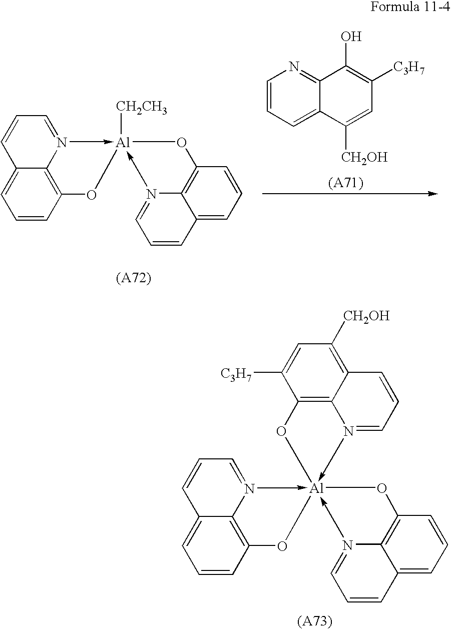

First, a xylene solution (30 mL) of the aluminum complex (A72) synthesized in the above procedures was dripped into the xylene solution (15 mL) of the 8-quinolinol derivative (A71) (3 mmol) for 1 hour at room temperature.

Thereafter, this reactive mixture was stirred for 8 hours at room temperature.

This reactive mixture was then vacuum concentrated, and the deposited solid was washed with a small amount of xylene.

The resultant solid was recrystallizated using methylene chloride, thereby obtaining the alcohol (A73) of the aluminum complex.

An epoxy group was then introduced to the alcohol by a similar synthetic route as the one represented by formula 6-5, thereby obtaining the polymerizable aluminum complex (A7).

Confirmation of the obtained polymerizable aluminum complex (A7) was performed using devices such as ¹H NMR and FT-IR.

### Synthesis of Polymerizable Aluminum Complex (A8) Represented by Formula 12

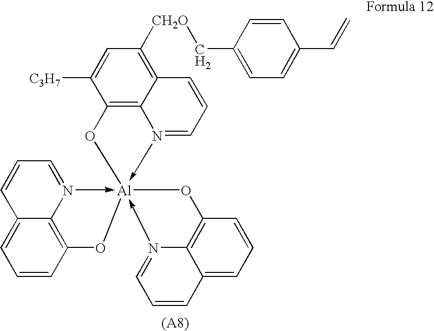

A polymerizable aluminum complex (A8) is a compound that emits green light.

The synthesis of this polymerizable aluminum complex (A8) was similar to that of the polymerizable aluminum complex (A7), except for using vinylbenzyl chloride instead of epichlorohydrin.

### Synthesis of Polymerizable Vinylcarbazole-Styrene Copolymer (1) Represented by Formula 13-1

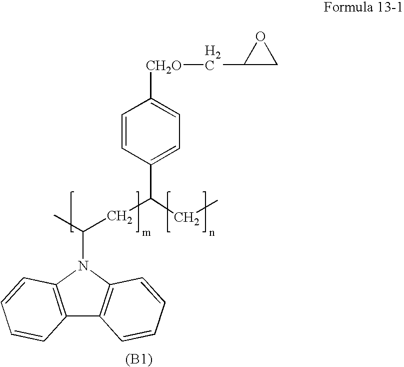

First, a 4-vinylbenzyl ether derivative (styrene derivative) (B11) was synthesized using a synthetic route represented in formula 13-2 attached below.

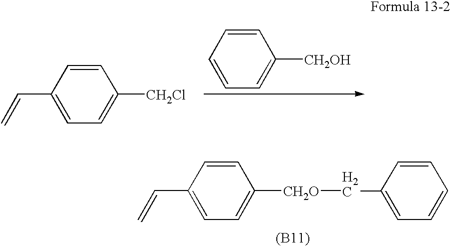

Polymerizable vinylcarbazole-styrene copolymer (B1) is a compound that emits blue light.

First, 4-vinylbenzyl ether derivative (B11) was synthesized using 4-vinylbenzyl chloride (Sigma-Aldrich Corporate) and benzyl alcohol.

Thereafter, ether derivative (B12) of vinylcarbazol-styrene copolymer was synthesized using the synthetic route represented in formula 13-3 attached below.

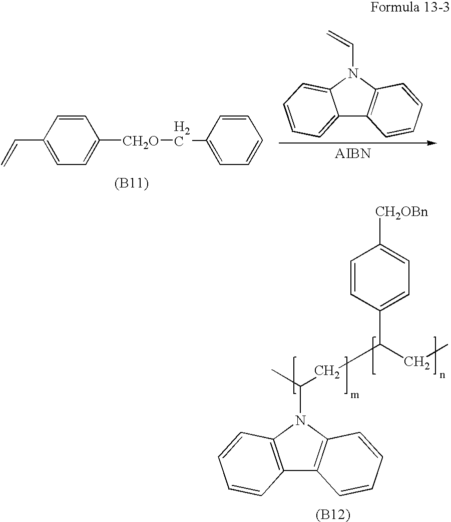

A xylene solution of 4-vinylbenzyl ether derivative (10 mmol) and N-vinylcarbazol (100 mmol: Tokyo Chemical Industry Co.; Ltd) was prepared, and azoisobutyronitrile (AIBN: 1 mmol) was added.

Subsequently, after removing dissolved oxygen by a nitrogen bubbling, the solution was heated to 80° C. and was stirred for 12 hours.

Methanol was then added to this reactive mixed solution, so as to extract the deposited solid.

The extracted solid was dissolved again into xylene, and deposited by methanol. After repeating the procedure twice, the solvent was removed, and the benzyl ether derivative (B12) of the vinylcarbazol-styrene copolymer was obtained.

The epoxy group was then introduced to the above-obtained derivative by a similar synthetic route as the one represented by formula 6-5, thereby obtaining the polymerizable vinylcarbazole-styrene copolymer (epxoy-containing vinylcarbazole-styrene copolymer) (B1).

Confirmation of the obtained polymerizable vinylcarbazole-styrene copolymer (B1) was performed using devices such as ¹H NMR and

### Synthesis of Polymerizable Vinylcarbazole-Styrene Copolymer (B2) Represented by Formula 14

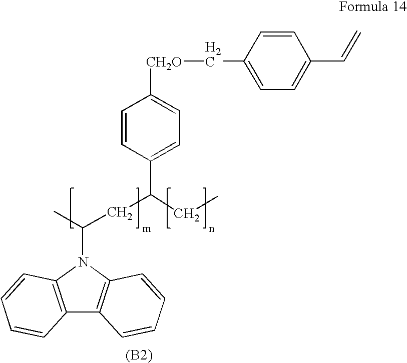

The synthesis of a polymerizable vinylcarbazole-styrene copolymer (B2) was similar to that of the polymerizable vinylcarbazole-styrene copolymer (B1), except for using 4-vinylbenzyl chloride instead of epichlorohydrin.

### Synthesis of Polymerizable Oxadiazie Derivative (C1) Represented by Formula 15-1

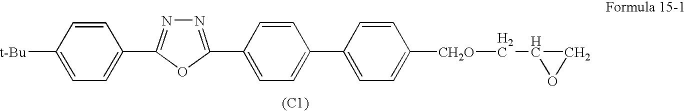

First, biphenyldicarboxylic acid ethyl ester (C13) was synthesized using the synthetic route represented in formula 15-2 attached below.

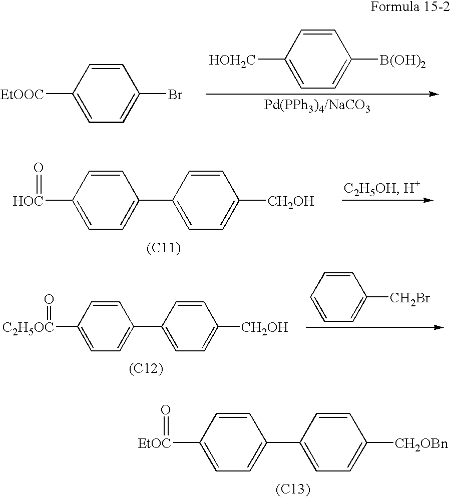

Tetrakis(triphenylphosphine)palladium(0) (3 mmol) and 4-(hydroxymethyl)phenylboronic acid (10 mmol: Sigma-Aldrich Corporate) were added to a toluene solution of 4-bromobenzoic acid methyl (10 mmol), and the mixed solution was stirred.

A sodium carbonate solution was then added to this mixed solution, and was heated to reflux for 24 hours.

After the reaction was completed, methylene chloride/water was added to this reactive mixture and an aqueous layer was extracted using an organic solvent. The mixture was dried with anhydrous magnesium sulfate, and the redundant solvent of the mixture was removed in a reduced pressure, thereby obtaining a biphenylcarboxylic acid derivative (C11) (yield 60%).

Thereafter, the biphenylcarboxylic acid derivative (C11) was reacted with ethanol in the sulfuric acidity, so as to ethyl esterify (C12) a carboxyl group. The hydroxyl group thereof was converted to a benzyl protective group by the reaction with benzyl bromide, thereby obtaining biphenylcarboxylic acid ethyl ester (C13).

Subsequently, a biphenylcarboxylic acid hydrazide derivative (C14) was synthesized using the synthetic route represented in formula 15-3 attached below.

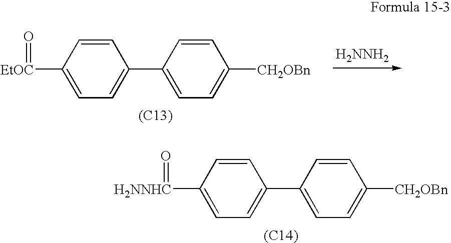

The biphenylcarboxylic acid hydrazide derivative (C14) was obtained by having a hydrazine solution react with a suspended ethanol solution of biphenylcarboxylic acid ethyl ester (C13) (10 mmol) synthesized in the previous procedures.

Subsequently, a hydrazine intermediate (C15) was synthesized using the synthetic route represented in formula 15-4 attached below.

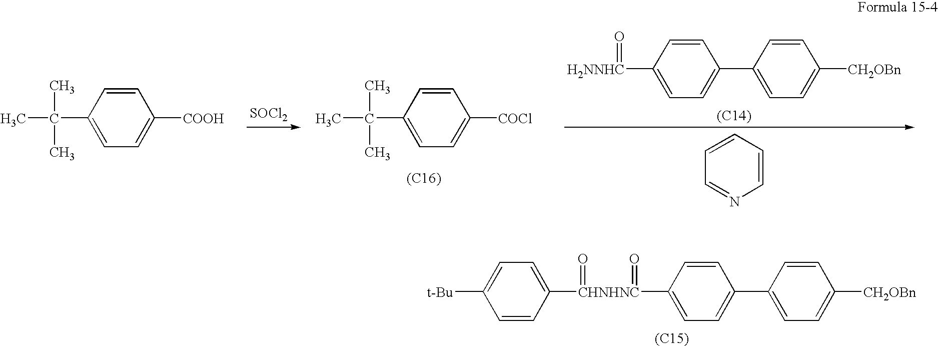

4-t-butylbenzoic acid (10 mmol) and thionyl chloride (25 mL,) were put into a well dried flask, and were gently heated to reflux for 5 hours in the nitrogen stream, thereby obtaining 4-t-butylbenzoyl chloride (C16).

After removing the excessive thionyl chloride in a reduced pressure, pyridine 100 mL were added, at room temperature, to 4-t-butylbenzoyl chloride (C16) synthesized in the previous procedure. In addition, the biphenylearboxylic acid hydrazide derivative (C14) (10 mmol) synthesized in the previous procedure was added to the mixture in small quantities. The system produces heat, changing from suspended to a consistent solution.

After stirring this mixed solution in a nitrogen stream for 30 minutes at room temperature, the solution was further stirred for 3 hours while heated by oil bath at 50° C.

Thereafter, by pouring the reactive resultant solution into a large amount of ice water, the powdered solid product was deposited. This solid product was filtered out, and then washed, first with water and then with methanol, and was dried, thereby obtaining the hydrazine intermediate (C15) (yield 75%).

Subsequently, an oxadiazole derivative (C17) was synthesized using a synthetic route represented in formula 15-5 attached below.

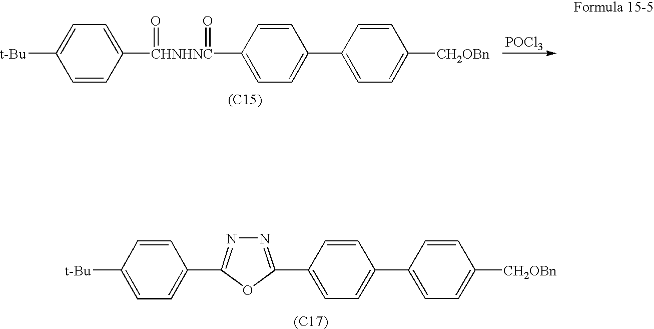

First, dehydration of the hydrazine intermediate (C15) synthesized in the previous procedures was carried out by: adding phosphoryl chloride 10 mL to anhydrous xylene solution of the hydrazine intermediate (10 mmol); thereafter gently heating to refulx for 6 hours in a nitrogen stream.

A significant portion of xylene and phosphoryl chloride contained in the reactive resultant solution was removed by a reduced-pressure distillation, and thereafter, the suspended solution was prepared by carefully adding a large amount of water while cooling with ice.

Subsequently, the powdered solid product was deposited by neutralizing the resultant suspended solution with a sodium hydroxide solution and by filtering this suspended solution. This solid product was washed, first with water and then with methanol, and was dried, thereby obtaining the oxadiazole derivative (C17) (yield 65%).

The epoxy group was then introduced to this derivative by a similar synthetic route as the one represented by formula 6-5, thereby obtaining a polymerizable oxadiazole derivative (C1).

Confirmation of the obtained polymerizable oxadiazole derivative (C1) was performed using devices such as ¹H NMR and FT-IR.

### Synthesis of Polymerizable Oxactiazole Derivative (C2) Represented by Formula 16

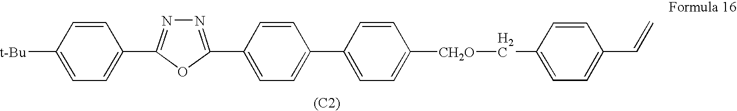

The synthesis of a polymerizable oxadiazole derivative (C2) was similar to that of the polymerizable oxadiazole derivative (C1), except for using 4-vinylbenzyl chloride instead of epichlorohydrin.

### Synthesis of Polymerizable Triphenylamine Derivative (D1) Represented by Formula 17-1

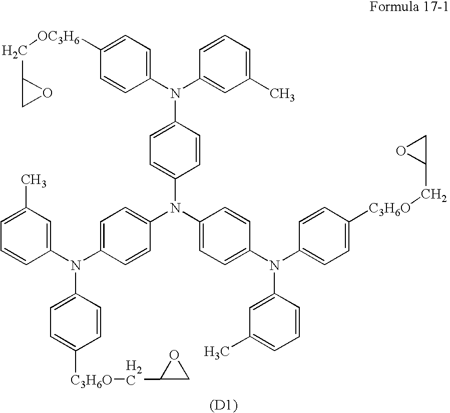

A polymerizable triphenylamine derivative (D1) was synthesized using the synthetic route represented in formula 17-2 attached below.

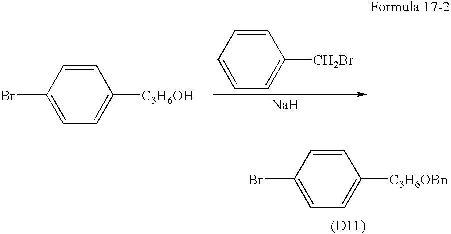

3-(p-bromophenyl)propanol was processed with benzyl bromide and sodium hydroxide in anhydrous dimethylformamide, so as to convert the hydroxyl group into the benzyl ether group, obtaining a benzyl ether derivative (D11).

At the same time, a 3-methylbenzamide derivative (D12) was synthesized using the synthetic route represented in formula 17-3 attached below.

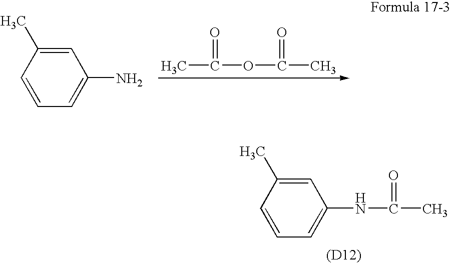

M-toluidine (1 mol) was dissolved into acetic acid (150 mL), and the solution was stirred after dripping acetic anhydride into it at room temperature.

After the reaction was completed, the deposited solid was filtered, washed, and dried to obtain the 3-methylbenzamide derivative (D12).

Thereafter, a diphenylamine derivative (D13) was synthesized using the synthetic route represented in formula 17-4 attached below.

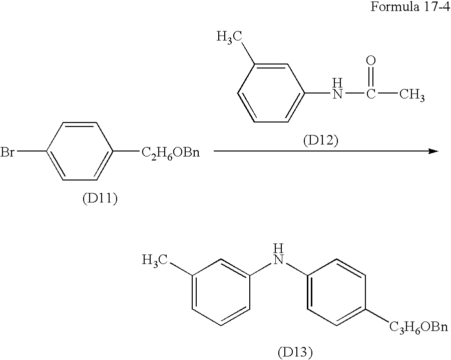

The benzyl ether derivative (D11) (0.5 mol), the 3-methylbenzamide derivative (D12) (0.6 mol), potassium carbonate (1.1 mol), copper powder, and iodine were mixed and heated at 200° C.

After standing the mixture to cool, a diphenylamine derivative (D13) was obtained by adding isoamyl alcohol (130 mL), pure water (50 mL), and potassium hydroxide (0.73 mol), and thereafter drying the resultant.

Subsequently, a triphenylamine derivative (D14) was synthesized using the synthetic route represented in formula 17-5 attached below.

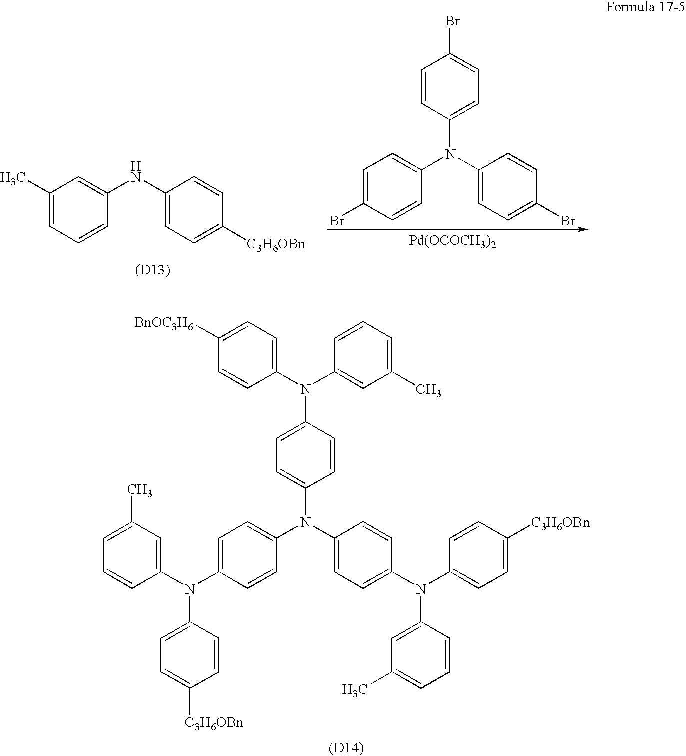

The diphenylamine derivative (D13) (200 mmol) synthesized in the previous procedure, tris(4-bromophenyl)amine (60 mmol), palladium acetate (2.1 mmol), t-butylphosphine (8.4 mmol), t-butoxysodium (400 mmol), and xylene (600 mL) were mixed and stirred at 120° C.

This reactive solution was stand to cool, and the deposited solid was filtered, and then washed with a small amount of xylene, thereby obtaining the triphenylamine derivative (D14).

The epoxy group was then introduced to this derivative by a similar synthetic route as the one represented by formula 6-5, thereby obtaining the polymerizable triphenylamine derivative (D1).

Confirmation of the obtained polymerizable triphenylamine derivative (D1) was performed using devices such as ¹H NMR and FT-IR.

### Synthesis of Polymerizable triphenylamine Derivative (D2) Represented by Formula 18

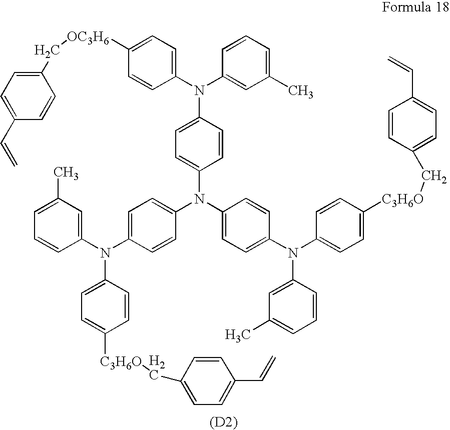

The synthesis of a polymerizable triphenylamine derivative (D2) was similar to that of polymerizable triphenylamine derivative (D1), except for using 4-vinylbenzyl chloride instead of epichlorohydrin.

### Synthesis of Polymerizable Arylamine Derivative (E1) Represented by Formula 19-1

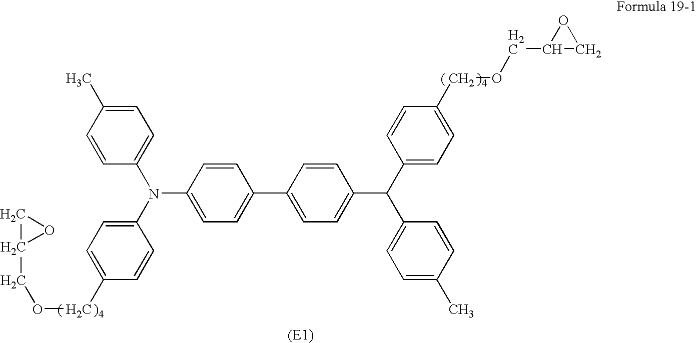

A polymerizable arylamin derivative (E1) was synthesized using the synthetic route represented in formula 19-2 attached below.

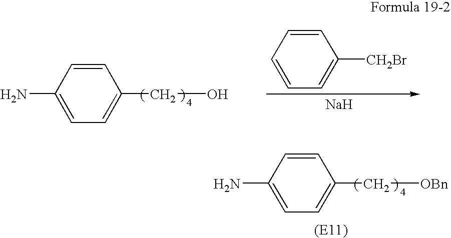

First, 1-(p-aminophenyl)butanol was processed with benzyl bromide and sodium hydroxide in anhydrous dimethylformamide, so as to convert the hydroxyl group into the benzyl ether group, obtaining a benzyl ether derivative (E11).

Thereafter, a benzamide derivative (E12) was synthesized from the benzyl ether derivative (E11), using the synthetic route represented by formula 19-3 attached below.

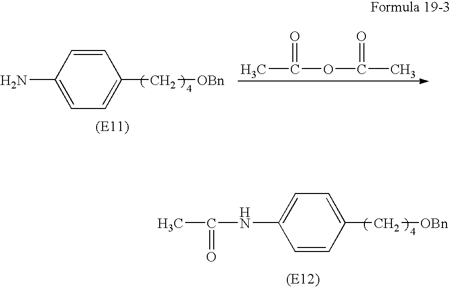

The benzyl ether derivative (E11) (1 mol) was dissolved into acetic acid (150 mL), and the solution was stirred after dripping acetic anhydride into it at room temperature.

After the reaction was completed, the deposited solid was filtered, washed, and dried to obtain the benzamide derivative (E12).

A diphenylamine derivative (E13) was then synthesized using the synthetic route represented in formula 19-4 attached below.

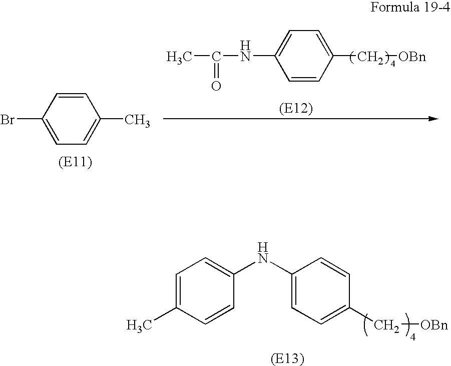

4-bromotoluene (0.5 mol), the benzamide derivative (E12) (0.6 mol), potassium carbonate (1.1 mol), copper powder, and iodine were mixed and heated at 200° C.

After standing the mixture to cool, the diphenylamine derivative (E13) was obtained by adding isoamyl alcohol (130 mL), pure water (50 mL), and potassium hydroxide (0.73 mol) and then drying the resultant.

Subsequently, an arylamin derivative (E14) was synthesized using the synthetic route represented in formula 19-5 attached below.

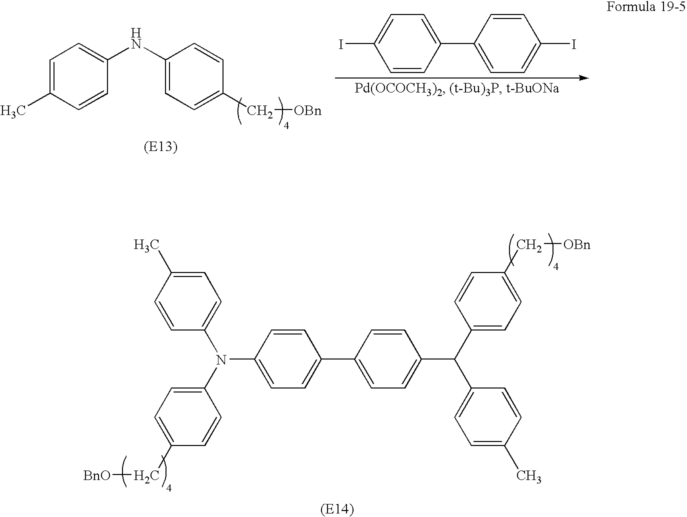

The diphenylamine derivative (E13) (130 mmol) synthesized in the previous procedure, 4′-diiodobiphenyl (62 mmol), palladium acetate (1.3 mmol), t-butylphosphine (5.2 mmol), t-butoxysodium (260 mmol), and xylene (700 mL) were mixed and stirred at 120° C.

This reactive solution was stand to cool, and the deposited solid was filtered and thereafter was washed with a small amount of xylene, thereby obtaining the arylamin derivative (E14).

The epoxy group was then introduced to this derivative by a similar synthetic route as the one represented by formula 6-5, thereby obtaining the polymerizable arylamin derivative (E1).

Confirmation of the obtained polymerizable arylamin derivative (E1) was performed using devices such as ¹H NMR and FT-IR.

### Synthesis of Polymerizable Arylamin Derivative (E2) Represented by Formula 20

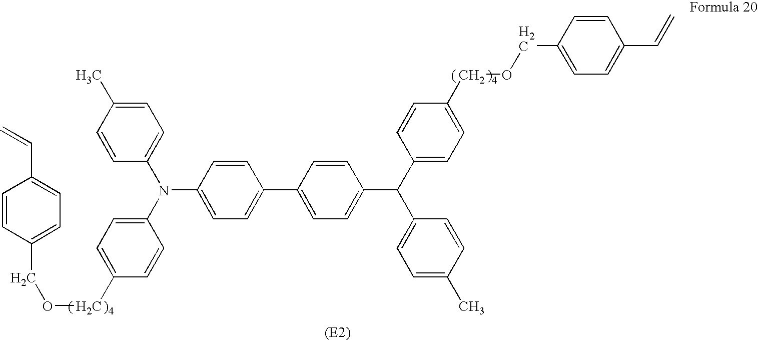

The synthesis of a polymerizable arylamin derivative (E2) was similar to that of polymerizable arylamin derivative (E1), except for using 4-vinylbenzyl chloride instead of epichlorohydrin.

2. Manufacturing Organic EL Element

### First Example

Preparation of Liquid Material

In order to prepare 1.0 wt % of liquid material, the following four materials were used as the first through fourth compounds, these materials being dissolved into xylene together with a photopolymerization initiator. The polymerizable iridium complex (A2) was used as the first compound provided with the emissive light-emitting moiety. The polymerizable arylamin derivative (E1) was used as the second compound provided with the hole-transporting hole transport moiety. The polymerizable oxadiazole derivative (C1) was used as the third compound provided with the electron-transporting electron transport moiety. The polymerizable vinylcarbazole-styrene copolymer (B1) was used as the fourth compound provided with the host moiety that supplies excitation energy to the light-emitting moiety. Finally, a cationic photopolymerization initiator (“FC-508”, Sumitomo 3M Ltd.) was used as the photopolymerization initiator.

The mixing ratio of the first compound, the sum of the second and the third compound, and the fourth compound was 3:70:30 by weight. The weight ratio of the sum of the first through fourth compounds to the cationic photopolymerization initiator was 99:1.

Fabricating an Organic EL Element

1. An ITO electrode (anode) having an average thickness of 100 nm was formed on a transparent glass substrate having an average thickness of 0.5 mm with a vacuum deposition.

2. A film was formed by applying and drying the liquid material on the ITO electrode.

Thereafter, the first to fourth compounds were polymerized so as to form an organic EL layer (light-emitting layer) composed of a random copolymer, the layer having an average thickness of 50 nm. Polymerization was done by irradiating ultra violet light (wavelength 365 nm, irradiation intensity 500 mW/cm²) in a dry atmosphere for 15 seconds, thereafter heating the material for 60 minutes at 110° C., using a mercury lamp (“UM-452” USHIO Inc.) with a filter.

3. A CaAl electrode (cathode) having an average thickness of 300 nm was formed on the organic EL layer by sequentially supplying Ca and Al on the layer with the vacuum deposition.

4. A protection cover formed with polycarbonate was deposited so as to cover the anode, the organic EL layer, and the cathode formed in the above procedure. Thereafter, these were fixed and sealed with ultraviolet curing resin, thereby completing the organic EL element.

### Second Example

Preparation of Liquid Material

In order to prepare 1.0 wt % of liquid material, the following four materials were used as the first through fourth compounds, these materials being dissolved into xylene together with a photopolymerization initiator. The polymerizable iridium complex (A4) was used as the first compound provided with the emissive light-emitting moiety. The polymerizable triphenylamine derivative (D1) was used as the second compound provided with the hole-transporting hole transport moiety. The polymerizable oxadiazole derivative (C1) was used as the third compound provided with the electron-transporting electron transport moiety. The polymerizable vinylcarbazole-styrene copolymer (B1) was used as the fourth compound provided with the host moiety that supplies excitation energy to the light-emitting moiety. Finally, a cationic photopolymerization initiator (“FC-508”, Sumitomo 3M Ltd.) was used as the photopolymerization initiator.

The mixing ratio of the first compound, the sum of the second and third compounds, and the fourth compound was 3:70:30 by weight. The weight ratio of the sum of the first through fourth compounds to the cationic photopolymerization initiator was 99:1.

Fabricating an Organic EL Element

The organic EL element was manufactured in the same manner as that of the first example, except for using the liquid material described above.

### Third Example

Preparation of Liquid Material

In order to prepare 1.0 wt % of liquid material, the following four materials were used as the first through fourth compounds, these materials being dissolved into xylene together with a photopolymerization initiator. The polymerizable iridium complex (A5) was used as the first compound provided with the emissive light-emitting moiety. The polymerizable triphenylamine derivative (D1) and the polymerizable arylamin derivative (E1) were used as the second compound provided with the hole-transporting hole transport moiety. The polymerizable oxadiazole derivative (C1) was used as the third compound provided with the electron-transporting electron transport moiety. The polymerizable vinylcarbazole-styrene copolymer (B1) was used as the fourth compound provided with the host moiety that supplies excitation energy to the light-emitting moiety. Finally, a cationic photopolymerization initiator (“FC-508”, Sumitomo 3M Ltd.) was used as the photopolymerization initiator.

The mixing ratio of the first compound, the sum of the second and third compound, and the fourth compound was 3:70:30 by weight. The weight ratio of the sum of the first through fourth compounds to the cationic photopolymerization initiator was 99:1.

Fabricating an Organic EL Element

The organic EL element was manufactured in the same manner as that of the first example, except for using the liquid material described above.

### Fourth Example

Preparation of Liquid Material

In order to prepare 1.0 wt % of liquid material, the following four materials were used as the first through fourth compounds, these materials being dissolved into xylene together with a photopolymerization initiator. The polymerizable iridium complex (A6) was used as the first compound provided with the emissive light-emitting moiety. The polymerizable triphenylamine derivative (D1) and the polymerizable arylamin derivative (E1) were used as the second compound provided with the hole-transporting hole transport moiety. The polymerizable oxadiazole derivative (C1) was used as the third compound provided with the electron-transporting electron transport moiety. The polymerizable vinylcarbazole-styrene copolymer (B1) was used as the fourth compound provided with the host moiety that supplies excitation energy to the light-emitting moiety. Finally, a cationic photopolymerization initiator (“FC-508”, Sumitomo 3M Ltd.) was used as the photopolymerization initiator.

The mixing ratio of the first compound, the sum of the second and third compound, and the fourth compound was 3:70:30 by weight. The weight ratio of the sum of the first through fourth compounds to the cationic photopolymerization initiator was 99:1.

Fabricating an Organic EL Element

The organic EL element was manufactured in the same manner as that of the first example, except for using the liquid material described above.

### Fifth Example

Preparation of Liquid Material

In order to prepare 1.0 wt % of liquid material, the following four materials were used as the first through fourth compounds, these materials being dissolved into xylene together with a photopolymerization initiator. The polymerizable aluminium complex (A7) was used as the first compound provided with the emissive light-emitting moiety. The polymerizable triphenylamine derivative (D1) and the polymerizable arylamin derivative (E1) were used as the second compound provided with the hole-transporting hole transport moiety. The polymerizable oxadiazole derivative (C1) was used as the third compound provided with the electron-transporting electron transport moiety. Finally, a cationic photopolymerization initiator (“FC-508”, Sumitomo 3M Ltd.) was used as the photopolymerization initiator.

The mixing ratio of the first compound and the sum of the second and third compounds was 30:70 by weight. The weight ratio of the sum of the first through third compounds to the cationic photopolymerization initiator was 99:1.

Fabricating an Organic EL Element

The organic EL element was manufactured in the same manner as that of the first example, except for using the liquid material described above.

### Sixth Example

Preparation of Liquid Material

In order to prepare 1.0 wt % of liquid material, the following four materials were used as the first through fourth compounds, these materials being dissolved into xylene together with a photopolymerization initiator. The polymerizable vinylcarbazole-styrene copolymer (B1) was used as the first compound provided with the emissive light-emitting moiety. The polymerizable triphenylamine derivative (D1) and the polymerizable arylamin derivative (E1) were used as the second compound provided with the hole-transporting hole transport moiety. The polymerizable oxadiazole derivative (C1) was used as the third compound provided with the electron-transporting electron transport moiety. Finally a cationic photopolymerization initiator (“FC-508”, Sumitomo 3M Ltd.) was used as the photopolymerization initiator.

The mixing ratio of the first compound and the sum of the second and third compounds was 30:70 by weight. The weight ratio of the sum of the first through third compounds to the cationic photopolymerization initiator was 99:1.

Fabricating an Organic EL Element

The organic EL element was manufactured in the same manner as that of the first example, except for using the liquid material described above.

### Seventh Example

Preparation of Liquid Material

In order to prepare 1.0 wt % of liquid material, the following four materials were used as the first through fourth compounds, these materials being dissolved into xylene together with a photopolymerization initiator. The polymerizable iridium complex (A1) was used as the first compound provided with the emissive light-emitting moiety. The polymerizable arylamin derivative (E2) was used as the second compound provided with the hole-transporting hole transport moiety. The polymerizable oxadiazole derivative (C2) was used as the third compound provided with the electron-transporting electron transport moiety. The polymerizable vinylcarbazole-styrene copolymer (B2) was used as the fourth compound provided with the host moiety that supplies excitation energy to the light-emitting moiety. Finally, a photoradical polymerization initiator (“IRGACURE 651”, Nagase & Co., Ltd.) was used as the photopolymerization initiator.

The mixing ratio of the first compound, the sum of the second and third compound, and the fourth compound was 3:70:30 by weight. The weight ratio of the sum of the first through fourth compounds to the photoradical polymerization initiator was 99.5:0.5.

Fabricating an Organic EL Element

The organic EL element was manufactured in the same manner as that of the first example, except for using the process 2′ described hereafter instead of the process 2 referred to in the first example.

2′. A film was formed by applying and drying the liquid material on the ITO electrode.

Thereafter, the first to fourth compounds were polymerized so as to form an organic EL layer (light-emitting layer) composed of a random copolymer, the layer having an average thickness of 50 nm. Polymerization was done by irradiating an ultra violet light (wavelength 365 nm, irradiation intensity 2 mW/cm²) in an argon gas atmosphere for 300 seconds, using a mercury lamp (“UM-452” USHIO Inc.) with a filter.

### Eighth Example

Preparation of Liquid Material

In order to prepare 1.0 wt % of liquid material, the following four materials were used as the first through fourth compounds, these materials being dissolved into xylene together with a photopolymerization initiator. The polymerizable iridium complex (A3) was used as the first compound provided with the emissive light-emitting moiety. The polymerizable triphenylamine derivative (D2) was used as the second compound provided with the hole-transporting hole transport moiety. The polymerizable oxadiazole derivative (C2) was used as the third compound provided with the electron-transporting electron transport moiety. The polymerizable vinylcarbazole-styrene copolymer (B2) was used as the fourth compound provided with the host moiety that supplies excitation energy to the light-emitting moiety. Finally, a photoradical polymerization initiator (“IRGACURE 651”, Nagase & Co., Ltd.) was used as the photopolymerization initiator.

The mixing ratio of the first compound, the sum of the second and third compound, and the fourth compound was 3:70:30 by weight. The weight ratio of the sum of the first through fourth compounds to the photoradical polymerization initiator was 99.5:0.5.

Fabricating an Organic EL Element

The organic EL element was manufactured in the same manner as that of the seventh example, except for using the liquid material described above.

### Ninth Example

Preparation of Liquid Material

In order to prepare 1.0 wt % of liquid material, the following four materials were used as the first through fourth compounds, these materials being dissolved into xylene together with a photopolymerization initiator. The polymerizable aluminium complex (A8) was used as the first compound provided with the emissive light-emitting moiety. The polymerizable arylamin derivative (E2) was used as the second compound provided with the hole-transporting hole transport moiety. The polymerizable oxadiazole derivative (C2) was used as the third compound provided with the electron-transporting electron transport moiety. Finally, a photoradical polymerization initiator (“IRGACURE 651”, Nagase & Co., Ltd.) was used as the photopolymerization initiator.

The mixing ratio of the first compound and the sum of the second and third compounds was 30:70 by weight. The weight ratio of the sum of the first through third compounds to the photoradical polymerization initiator was 99.5:0.5.

Fabricating an Organic EL Element

The organic EL element was manufactured in the same manner as that of the seventh example, except for using the liquid material described above.

### Tenth Example

Preparation of Liquid Material

In order to prepare 1.0 wt % of liquid material, the following four materials were used as the first through fourth compounds, these materials being dissolved into xylene together with a photopolymerization initiator. The polymerizable vinylcarbazole-styrene copolymer (B2) was used as the first compound provided with the emissive light-emitting moiety. The polymerizable arylamin derivative (E2) was used as the second compound provided with the hole-transporting hole transport moiety. The polymerizable oxadiazole derivative (C2) was used as the third compound provided with the electron-transporting electron transport moiety. Finally, a photoradical polymerization initiator (“IRGACURE 651”, Nagase & Co., Ltd.) was used as the photopolymerization initiator.

The mixing ratio of the first compound and the sum of the second and third compounds was 30:70 by weight. The weight ratio of the sum of the first through third compounds to the photoradical polymerization initiator was 99.5:0.5.

Fabricating an Organic EL Element

The organic EL element was manufactured in the same manner as that of the seventh example, except for using the liquid material described above.

The light-emitting intensity (cd/m²), the maximum luminous efficiency (1 m/W), and the time it takes for the light-emitting intensity to decay down to half of the initial value (half life) were measured for all of the above referenced examples, by impressing 6V voltage between the anode and cathode. All of the examples exhibited superior results, having excellent light-emitting characteristics.

The entire disclosure of Japanese Patent Application No: 2006-077831, filed Mar. 20, 2006 is expressly incorporated by reference herein.

What is claimed is:

1. A method of manufacturing a light-emitting element, comprising:
forming a film over a first electrode, the film including a first compound, a second compound, and a third compound, the first compound being provided with an emissive light-emitting moiety and at least one first polymerizable group, the second compound being provided with a hole-transporting hole transport moiety and at least one second polymerizable group, and the third compound being provided with an electron-transporting electron transport moiety and at least one third polymerizable group;
forming a organic layer by polymerizing the first, second, and third compounds in the film; and
forming a second electrode over the organic layer.

2. A method of manufacturing a light-emitting element, comprising:
forming a first film over a first electrode, the first film including at least a second compound and a third compound, the second compound being provided with a hole-transporting hole transport moiety and at least one second polymerizable group, and the third compound being provided with an electron-transporting electron transport moiety and at least one third polymerizable group;
forming a first organic layer by polymerizing the second and third compounds in the first film; and
forming a second electrode over the organic layer.

3. The method of manufacturing a light-emitting element according to claim 2, further comprising:
forming a second organic layer over the first organic layer before the process of forming the second electrode, the second organic layer including a first compound that is provided with an emissive light-emitting moiety.

4. The method of manufacturing a light-emitting element according to claim 2, further comprising:
forming a second film over the first organic layer before the process of forming the second electrode, the second film including at least a first compound that is provided with an emissive light-emitting moiety and at least one first polymerizable group;
forming a second organic layer before the process of forming the second electrode, the second organic layer being formed by polymerizing at least the first compound in the second film.

5. A method of manufacturing a light-emitting element, comprising:
forming a film over a first electrode, the film including and a third compound, the first compound and at least one first polymerizable group, and the third compound being provided with an electron-transporting electron transport moiety and at least one third polymerizable group;
forming a organic layer by polymerizing the first and third compounds in the film; and
forming a second electrode over the organic layer.

6. The method of manufacturing a light-emitting element according to claim 1, the film being formed with a liquid phase process.

7. The method of manufacturing a light-emitting element according to claim 1, in the process of forming the organic layer, the first, second, and third compounds being polymerized by light irradiation.

8. The method of manufacturing a light-emitting element according to claim 1, in the process of forming the organic layer, the first, second, and third compounds being polymerized by heating.

9. The method of manufacturing a light-emitting element according to claim 1, the first compound including a plurality of the first polymerizable groups.

10. The method of manufacturing a light-emitting element according to claim 1, each of the first, second, and third polymerizable groups being a cation polymerizable group.

11. The method of manufacturing a light-emitting element according to claim 1, each of the first, second, and third polymerizable groups being a radical polymerizable group.

12. The method of manufacturing a light-emitting element according to claim 1, the hole transport moiety including an arylamin skeleton.

13. The method of manufacturing a light-emitting element according to claim 1, the electron transport moiety including at least one of an oxadiazole skeleton and a triazole skeleton.

14. The method of manufacturing a light-emitting element according to claim 1, the light-emitting moiety including at least one of a fluorenone skeleton and a carbazol skeleton.

15. The method of manufacturing a light-emitting element according to claim 1, the light-emitting moiety including at least one of an iridium complex and an aluminum complex.

16. The method of manufacturing a light-emitting element according to claim 1, the film including a fourth compound provided with a host moiety supplying an excitation energy to the light-emitting moiety.

17. The method of manufacturing a light-emitting element according to claim 1, the film including a fourth compound provided with a host moiety supplying an excitation energy to the light-emitting moiety, the fourth compound including a fourth polymerizable group.

18. The method of manufacturing a light-emitting element according to claim 1, the film including a fourth compound provided with a host moiety supplying an excitation energy to the light-emitting moiety, the host moiety including at least one of an arylamin skeleton, a carbazol skeleton, and a fluorenone skeleton.

19. A method of manufacturing a light-emitting device including the method of manufacturing a light-emitting element according to claim 1.

20. A method of manufacturing an electronic apparatus including the method of manufacturing a light-emitting device according to claim 19.
